(19) United States
(12) Patent Application Publication
(10) Pub. No.: US 2024/0297741 A1
(43) Pub. Date: Sep. 5, 2024

(54) COMMUNICATION APPARATUS AND COMMUNICATION METHOD

(71) Applicant: SHARP KABUSHIKI KAISHA, Sakai City, Osaka (JP)

(72) Inventors: RYOTA YAMADA, Sakai City, Osaka (JP); Takuhiro SATO, Sakai City, Osaka (JP); HIROMICHI TOMEBA, Sakai City, Osaka (JP); ATSUSHI SHIRAKAWA, Sakai City, Osaka (JP)

(21) Appl. No.: 18/570,751

(22) PCT Filed: Jun. 21, 2022
(86) PCT No.: PCT/JP2022/024645

§ 371 Date: Dec. 15, 2023

(30) Foreign Application Priority Data
Jun. 21, 2021 (JP) 2021-102165

(51) Int. Cl. H04L 1/1812; H04L 1/00

(52) U.S. Cl. CPC H04L 1/1812; H04L 1/0003; H04L 1/0061

(57) ABSTRACT

A communication apparatus includes a higher layer unit configured to configure a retransmission scheme, a physical layer frame generator configured to generate a frame using a codeword, and a radio transmitter configured to transmit the frame. In a case that a configuration of the retransmission scheme indicates a Hybrid Auto Repeat reQuest (HARQ), the physical layer frame generator encodes, at a prescribed coding rate, a Low Density Parity Check (LDPC) information block including information bits to generate a parity bit sequence, and divides the parity bit sequence into blocks the number of which is given by a coding rate indicated by a Modulation and Coding Scheme (MCS), to generate multiple parity blocks. Each of the parity blocks is associated with the number of retransmissions. The codeword is generated based on the information bits and one of the parity blocks.

### TECHNICAL FIELD

The present invention relates to a communication apparatus and a communication method.

This application claims priority to JP 2021-102165 filed on Jun. 21, 2021, the contents of which are incorporated herein by reference.

### BACKGROUND ART

The Institute of Electrical and Electronics Engineers Inc. (IEEE) has been continuously working to update the IEEE 802.11 specification that is a wireless Local Area Network (LAN) standard in order to achieve a higher speed and frequency efficiency of wireless LAN communication. The recent rapid spread of wireless LAN devices is expected to expand the usage of wireless LAN devices as real-time applications such as remote medical care and VR/AR, and efforts are being made to standardize IEEE 802.11be to realize a further reduction in latency and a further increase in communication capacity in the IEEE 802.1 lax standard.

In the IEEE 802.11 standard, error control is introduced as a technique for increasing the throughput. Error control is roughly divided into Forward Error Correction (FEC) and Automatic repeat request (ARQ). The forward error correction is a system in which an error occurring in a transmission path is corrected on a reception side using an error correction code, and eliminates the need for a retransmission request to retransmit an erroneous packet to a transmission side. The error correction capability is improved by increasing the ratio of redundant bits occupying a codeword. However, there is a trade-off relationship between the error correction capability and an increased amount of decoding processing, reduced transmission efficiency, or the like. On the other hand, ARQ is a scheme for requesting the transmission side to retransmit a packet that has not been properly decoded by the reception side. At the time of decoding, a packet error is detected by Medium Access Control (MAC) on the reception side, and the packet is discarded without being accumulated in a buffer. An ACKnowledgement (ACK) is transmitted to the transmission side in a case that the packet is successfully decoded, and a Negative ACKnowledgement (NACK) is transmitted to the transmission side in a case that a packet error is detected. Packet retransmission processing is performed by ARQ in a case that the NACK is transmitted to the transmission side or the ACK is not transmitted to the transmission side within a prescribed period. In addition to the error control in the above-mentioned IEEE 802.11 standard, Hybrid ARQ (HARQ) corresponding to a combination of a forward error correction code and ARQ has been studied in IEEE 802.11be standardization activities. For the HARQ, wide studies have been conducted about chase combining in which at the time of retransmission, the same packet is transmitted to allow the reception side to perform combining to improve a Signal to Noise power ratio (SNR) of a received signal and Incremental redundancy (IR) in which at the time of retransmission, a redundant signal (parity signal) is newly transmitted to improve an error correction decoding capability on the reception side.

### CITATION LIST

### Non Patent Literature

NPL 1: IEEE 802.11-19/1578-00-0be, September 2018
NPL 2: IEEE 802.11-20/482-01-0be, June 2020

### SUMMARY OF INVENTION

### Technical Problem

However, since the conventional IEEE 802.11 standards do not consider the packet combining based on the HARQ, implementing efficient packet combining is difficult.

An aspect of the present invention has been made in view of such circumstances, and an object thereof is to provide a communication apparatus and a communication method that enable, in the IEEE 802.11 standard, efficient packet combining at the time of retransmission, contributing to improvement of a reception SNR.

### Solution to Problem

The communication apparatus and the communication method according to an aspect of the present invention for solving the aforementioned problem are as follows.

According to an aspect of the present invention, a communication apparatus includes a higher layer unit configured to configure a retransmission scheme, a physical layer frame generator configured to generate a frame using a codeword, and a radio transmitter configured to transmit the frame. In a case that a configuration of the retransmission scheme indicates a Hybrid Auto Repeat reQuest (HARQ), the physical layer frame generator encodes, at a prescribed coding rate, a Low Density Parity Check (LDPC) information block including information bits to generate a parity bit sequence, and divides the parity bit sequence into blocks the number of which is given by a coding rate indicated by a Modulation and Coding Scheme (MCS), to generate multiple parity blocks. Each of the multiple parity blocks is associated with the number of retransmissions, the codeword is generated based on the information bits and one of the multiple parity blocks. In a case that the LDPC information block includes the information bits and shortening bits, the number of bits of at least one parity block of the multiple parity blocks is reduced based on the number of shortening bits.

In the communication apparatus according to an aspect of the present invention, the number of blocks given by the coding rate indicated by the MCS increases as the coding rate increases.

In the communication device according to an aspect of the present invention, in the case that the LDPC information block includes the information bits and the shortening bits, the physical layer frame generator punctures a prescribed number of bits from the parity bit sequence and then divides the parity bit sequence into blocks the number of which is given by the coding rate indicated by the MCS to generate the multiple parity blocks.

In the communication device according to an aspect of the present invention, in the case that the LDPC information block includes the information bits and the shortening bits, the physical layer frame generator punctures a prescribed number of bits from one parity block, and generates the codeword based on the punctured parity block and the information bits.

In the communication device according to an aspect of the present invention, in the case that the LDPC information block includes the information bits and the shortening bits, the physical layer frame generator decreases, at a time of initial transmission, the number of bits of the parity block included in the codeword, based on the number of the shortening bits, and decreases, at a time of retransmission, the number of bits of the information bits included in the codeword, based on the number of the shortening bits.

According to an aspect of the present invention, a communication method includes the steps of configuring a retransmission scheme, generating a frame using a codeword, and transmitting the frame. In a case that a configuration of the retransmission scheme indicates a Hybrid Auto Repeat reQuest (HARQ), a Low Density Parity Check (LDPC) information block including information bits is encoded at a prescribed coding rate to generate a parity bit sequence, and the parity bit sequence is divided into blocks the number of which is given by a coding rate indicated by a Modulation and Coding Scheme (MCS), to generate multiple parity blocks. Each of the parity blocks is associated with the number of retransmissions, the codeword is generated based on the information bits and one of the parity blocks. In a case that the LDPC information block includes the information bits and shortening bits, the number of bits of at least one parity block among the multiple parity blocks decreases based on the number of shortening bits.

### Advantageous Effects of Invention

According to an aspect of the present invention, in the IEEE 802.11 standard, efficient packet combining is enabled at the time of retransmission, and the reception SNR is improved to allow for contribution to improvement of low-latency communication and an increase in user throughput.

### BRIEF DESCRIPTION OF DRAWINGS

FIG. 1 is a schematic diagram illustrating examples of splitting radio resources according to an aspect of the present invention.

FIG. 2 is a diagram illustrating an example of a frame structure according to an aspect of the present invention.

FIG. 3 is a diagram illustrating an example of a frame structure according to an aspect of the present invention.

FIG. 4 is a diagram illustrating an example of communication according to an aspect of the present invention.

FIG. 5 is a diagram illustrating a configuration example of a communication system according to an aspect of the present invention.

FIG. 6 is a block diagram illustrating a configuration example of a radio communication apparatus according to an aspect of the present invention.

FIG. 7 is a block diagram illustrating a configuration example of a radio communication apparatus according to an aspect of the present invention.

FIG. 8 is a schematic diagram illustrating an example of a modulation and coding scheme according to an aspect of the present invention.

FIG. 9 is a schematic diagram illustrating an example of a block length for LDPC coding processing according to an aspect of the present invention.

FIG. 10 is a schematic diagram illustrating an example of a block length for LDPC coding processing according to an aspect of the present invention.

FIG. 11 is a schematic diagram illustrating an example of a block length for LDPC coding processing according to an aspect of the present invention.

FIG. 12 is a schematic diagram illustrating an example of a block length for LDPC coding processing according to an aspect of the present invention.

FIG. 13 is a schematic diagram illustrating an example of a block length for LDPC coding processing according to an aspect of the present invention.

FIG. 14 is a schematic diagram illustrating an example of puncturing processing according to an aspect of the present invention.

FIG. 15 is a schematic diagram illustrating an example of puncturing processing according to an aspect of the present invention.

FIG. 16 is a schematic diagram illustrating an example of blocking processing according to an aspect of the present invention.

FIG. 17 is a schematic diagram illustrating an example of blocking processing according to an aspect of the present invention.

FIG. 18 is a schematic diagram illustrating control information related to a packet combining method of a PHY layer according to an aspect of the present invention.

### DESCRIPTION OF EMBODIMENTS

A communication system according to the present embodiment includes an access point apparatus (or also referred to as a base station apparatus) and a plurality of station apparatuses (or also referred to as a plurality of terminal apparatuses). The communication system and a network including the access point apparatus and the station apparatus will be referred to as a Basic service set (BSS: management range or cell). In addition, the station apparatus according to the present embodiment can have functions of the access point apparatus. Similarly, the access point apparatus according to the present embodiment can have functions of the station apparatus. Therefore, in a case that a communication apparatus is simply mentioned below, the communication apparatus can indicate both the station apparatus and the access point apparatus.

The base station apparatus and the terminal apparatuses in the BSS are assumed to perform communication based on Carrier sense multiple access with collision avoidance (CSMA/CA). Although the present embodiment is intended for an infrastructure mode in which a base station apparatus performs communication with multiple terminal apparatuses, the method of the present embodiment can also be performed in an ad hoc mode in which terminal apparatuses perform communication directly with each other. In the ad hoc mode, a terminal apparatus substitutes for a base station apparatus to form a BSS. The BSS in the ad hoc mode may also be referred to as an Independent Basic Service Set (IBSS). In the following description, a terminal apparatus that forms an IBSS in the ad hoc mode can also be considered to be a base station apparatus. The method of the present embodiment can also be implemented in Wi-Fi Direct (trade name) in which terminal apparatuses directly communicate with each other. In the Wi-Fi Direct, a terminal apparatus substitutes for a base station apparatus to form a Group. In the following description, a Group owner terminal apparatus that forms a Group in the Wi-Fi Direct can also be regarded as a base station apparatus.

In an IEEE 802.11 system, each apparatus can transmit transmission frames of multiple frame types in a common frame format. Each of the transmission frames is defined as a Physical (PHY) layer, a Medium access control (MAC) layer, or a Logical Link Control (LLC) layer. The physical layer will also be referred to as a PHY layer, and the medium access control layer will also be referred to as a MAC layer.

A transmission frame of the PHY layer will be referred to as a physical protocol data unit (PHY protocol data unit (PPDU) or physical layer frame). The PPDU includes a physical layer header (PHY header) including header information and the like for performing signal processing in the physical layer, a physical service data unit (PHY service data unit (PSDU) or MAC layer frame) that is a data unit processed in the physical layer, and the like. The PSDU can include an aggregated MAC protocol data unit (MPDU) (Aggregated MPDU (A-MPDU)) in which multiple MPDUs serving as retransmission units in a wireless section are aggregated.

A PHY header includes a reference signal such as a Short training field (STF) used for detection, synchronization, and the like of signals, a Long training field (LTF) used for obtaining channel information for demodulating data, and the like and a control signal such as a Signal (SIG) including control information for demodulating data. In addition, STFs are classified into a Legacy-STF (L-STF), a High throughput-STF (HT-STF), a Very high throughput-STF (VHT-STF), a High efficiency-STF (HE-STF), an Extremely High throughput-STF (EHT-STF), and the like in accordance with corresponding standards, and LTFs and SIGs are also similarly classified into an L-LTF, an HT-LTF, a VHT-LTF, an HE-LTF, an L-SIG, an HT-SIG, a VHT-SIG, an HE-SIG, and an EHT-SIG depending on the corresponding standards. The VHT-SIG is further classified into VHT-SIG-A1, VHT-SIG-A2, and VHT-SIG-B. Similarly, the HE-SIG is classified into HE-SIG-A1 to 4 and HE-SIG-B. In addition, on the assumption of technology update in the same standard, a Universal SIGNAL (U-SIG) field including additional control information can be included.

Furthermore, the PHY header can include information for identifying a BSS of a transmission source of the transmission frame (hereinafter, also referred to as BSS identification information). The information for identifying a BSS can be, for example, a Service Set Identifier (SSID) of the BSS or a MAC address of a base station apparatus of the BSS. In addition, the information for identifying a BSS can be a value unique to the BSS (e.g., a BSS Color, etc.) other than an SSID or a MAC address.

The PPDU is modulated in accordance with the corresponding standard. In the IEEE 802.11n standard, for example, the PPDU is modulated into an Orthogonal frequency division multiplexing (OFDM) signal.

The MPDU includes a MAC layer header (MAC header) including header information and the like for performing signal processing in the MAC layer, a MAC service data unit (MSDU) that is a data unit processed in the MAC layer or a frame body, and a Frame check sequence (FCS) for checking whether there is an error in the frame. In addition, multiple MSDUs can be aggregated as an Aggregated MSDU (A-MSDU).

The frame types of transmission frames of the MAC layer are roughly classified into three frame types, namely a management frame for managing an association state and the like between apparatuses, a control frame for managing a communication state between apparatuses, and a data frame including actual transmission data, and each frame type is further classified into a plurality of subframe types. The control frame includes a reception completion notification (Acknowledge (ACK)) frame, a transmission request (Request to send (RTS)) frame, a reception preparation completion (Clear to send (CTS)) frame, and the like. The management frame includes a Beacon frame, a Probe request frame, a Probe response frame, an Authentication frame, an Association request frame, an Association response frame, and the like. The data frame includes a Data frame, a polling (CF-poll) frame, and the like. Each apparatus can recognize the frame type and the subframe type of a received frame by interpreting contents of the frame control field included in the MAC header.

Note that an ACK may include a Block ACK. A Block ACK can give a reception completion notification with respect to multiple MPDUs. The ACK may include a Multi STA Block ACK (M-BA) including a reception completion notification for multiple communication apparatuses.

The beacon frame includes a Field in which a periodicity at which a beacon is transmitted (Beacon interval) and an SSID are described. The base station apparatus can periodically broadcast a beacon frame within a BSS, and each terminal apparatus can recognize the base station apparatus in the surroundings of the terminal apparatus by receiving the beacon frame. The action of the terminal apparatus recognizing the base station apparatus based on the beacon frame broadcast from the base station apparatus may be referred to as Passive scanning. On the other hand, the action of the terminal apparatus searching for the base station apparatus by broadcasting a probe request frame in the BSS may be referred to as Active scanning. The base station apparatus can transmit a probe response frame in response to the probe request frame, and details described in the probe response frame are equivalent to those in the beacon frame.

A terminal apparatus recognizes a base station apparatus and performs connection processing with respect to the base station apparatus. The connection processing is classified into an Authentication procedure and an Association procedure. A terminal apparatus transmits an authentication frame (authentication request) to a base station apparatus that the terminal apparatus desires to connect with. Once the base station apparatus receives the authentication frame, then the base station apparatus transmits, to the terminal apparatus, an authentication frame (authentication response) including a status code indicating whether authentication can be made for the terminal apparatus. The terminal apparatus can determine whether the terminal apparatus has been authenticated by the base station apparatus by interpreting the status code described in the authentication frame. Note that the base station apparatus and the terminal apparatus can exchange the authentication frame multiple times.

After the authentication procedure, the terminal apparatus transmits an association request frame to the base station apparatus in order to perform the association procedure. Once the base station apparatus receives the association request frame, the base station apparatus determines whether to allow the connection to the terminal apparatus and transmits an association response frame to notify the terminal apparatus of the intent. In the connection response frame, an Association identifier (AID) for identifying the terminal apparatus is described in addition to the status code indicating whether to perform the connection processing. The base station apparatus can manage multiple terminal apparatuses by configuring different AIDs for the terminal apparatuses for which the base station apparatus has allowed connection.

After the connection processing is performed, the base station apparatus and the terminal apparatus perform actual data transmission. In the IEEE 802.11 system, a Distributed Coordination Function (DCF), a Point Coordination Function (PCF), and mechanisms in which the aforementioned mechanisms are enhanced (an Enhanced distributed channel access (EDCA) or a hybrid control mechanism (Hybrid coordination function (HCF)), and the like) are defined. A case that the base station apparatus transmits signals to the terminal apparatus using the DCF will be described below as an example. However, the description also applies to a case that the terminal apparatus transmits signals to the base station apparatus using the DCF.

In the DCF, the base station apparatus and the terminal apparatus perform Carrier sense (CS) for checking usage of a radio channel in the surroundings of the apparatuses prior to communication. For example, in a case that the base station apparatus serving as a transmitting station receives a signal of a higher level than a predefined Clear channel assessment level (CCA level) on a radio channel, transmission of transmission frames on the radio channel is postponed. Hereinafter, a state in which a signal of a level that is equal to or higher than the CCA level is detected on the radio channel will be referred to as a busy (Busy) state, and a state in which a signal of a level that is equal to or higher than the CCA level is not detected will be referred to as an idle (Idle) state. In this manner, CS performed based on power of a signal actually received by each apparatus (reception power level) is called physical carrier sense (physical CS). Note that the CCA level is also called a carrier sense level (CS level) or a CCA threshold (CCAT). Note that in a case that a signal in a level that is equal to or higher than the CCA level is detected, the base station apparatus and the terminal apparatus start to perform an operation of demodulating at least a signal of the PHY layer.

The base station apparatus performs carrier sense in an inter-frame space (IFS) in accordance with the type of transmission frame to be transmitted and determines whether the radio channel is in a busy state or idle state. A period in which the base station apparatus performs carrier sense varies depending on the frame type and the subframe type of a transmission frame to be transmitted by the base station apparatus. In the IEEE 802.11 system, multiple IFSs with different periods are defined, and there are a short frame interval (Short IFS (SIFS)) used for a transmission frame with the highest priority given, a polling frame interval (PCF IFS (PIFS)) used for a transmission frame with a relatively high priority, a distribution control frame interval (DCF IFS(DIFS)) used for a transmission frame with the lowest priority, and the like. In a case that the base station apparatus transmits a data frame with the DCF, the base station apparatus uses the DIFS.

The base station apparatus waits by DIFS and then further waits for a random backoff time to prevent frame collision. In the IEEE 802.11 system, a random backoff time called a Contention window (CW) is used. CSMA/CA works with the assumption that a transmission frame transmitted by a certain transmitting station is received by a receiving station in a state in which there is no interference from other transmitting stations. Therefore, in a case that transmitting stations transmit transmission frames at the same timing, the frames collide against each other, and the receiving station cannot receive them properly. Thus, each transmitting station waits for a randomly configured time before starting transmission, and thus collision of frames can be avoided. In a case that the base station apparatus determines, through carrier sense, that a radio channel is in the idle state, the base station apparatus starts to count down a CW, acquires a transmission right for the first time after the CW becomes zero, and can transmit a transmission frame to the terminal apparatus. Note that, in a case that the base station apparatus determines through the carrier sense that the radio channel is in the busy state during the count-down of the CW, the base station apparatus stops the count-down of the CW. Thereafter, in a case that the radio channel becomes in the idle state, then the base station apparatus restarts the count-down of the remaining CW after the previous IFS.

Next, details of frame reception will be described. A terminal apparatus that is a receiving station receives a transmission frame, interprets the PHY header of the transmission frame, and demodulates the received transmission frame. Then, the terminal apparatus interprets the MAC header of the demodulated signal and thus can recognize whether the transmission frame is addressed to the terminal apparatus itself. Note that the terminal apparatus can also determine the destination of the transmission frame based on information described in the PHY header (for example, a group identifier (Group ID (GID)) described in VHT-SIG-A).

In a case that the terminal apparatus determines that the received transmission frame is addressed to the terminal apparatus and successfully demodulates the transmission frame without any error, the terminal apparatus is to transmit an ACK frame indicating the proper reception of the frame to the base station apparatus that is the transmitting station. The ACK frame is one of transmission frames with the highest priority transmitted only after a wait for the SIFS period (with no random backoff time). The base station apparatus ends the series of communication with the reception of the ACK frame transmitted from the terminal apparatus. Note that, in a case that the terminal apparatus is not able to receive the frame properly, the terminal apparatus does not transmit ACK. Thus, in a case that the ACK frame has not been received from the receiving station for a certain period (a length of SIFS+ACK frame) after the transmission of the frame, the base station apparatus considers the communication to be failed and ends the communication. In this manner, an end of a single communication operation (also called a burst) in the IEEE 802.11 system is to be determined based on whether an ACK frame is received, except for special cases such as a case of transmission of a broadcast signal such as a beacon frame, a case that fragmentation for splitting transmission data is used, or the like.

In a case that the terminal apparatus determines that the received transmission frame is not addressed to the terminal apparatus itself, the terminal apparatus configures a Network allocation vector (NAV) based on the Length of the transmission frame described in the PHY header or the like. The terminal apparatus does not attempt communication during the period configured in the NAV. In other words, because the terminal apparatus performs the same operation as in the case that the terminal apparatus determines the radio channel is in the busy state through physical CS for the period configured in the NAV, the communication control based on the NAV is also called virtual carrier sense (virtual CS). The NAV is also configured by a transmission request (Request to send (RTS)) frame or a reception preparation completion (Clear to send (CTS)) frame, which are introduced to solve a hidden terminal problem in addition to the case that the NAV is configured based on the information described in the PHY header.

Unlike the DCF in which each apparatus performs carrier sense and autonomously acquires the transmission right, with respect to the PCF, a control station called a Point coordinator (PC) controls the transmission right of each apparatus within a BSS. In general, a base station apparatus serves as a PC and acquires the transmission right of a terminal apparatus within a BSS.

A communication period using the PCF includes a non-period (Contention free period (CFP)) and a Contention period (CP). Communication is performed based on the aforementioned DCF during a CP, and a PC controls the transmission right during a CFP. The base station apparatus serving as a PC broadcasts a beacon frame with description of a CFP period (CFP Max duration) and the like in a BSS prior to communication with a PCF. Note that the PIFS is used for transmission of the beacon frame broadcast at the time of a start of transmission by the PCF, and the beacon frame is transmitted without waiting for the CW. The terminal apparatus that has received the beacon frame configures the CFP period described in the beacon frame in a NAV. Hereinafter, the terminal apparatus can acquire the transmission right only in a case that a signal (e.g., a data frame including CF-poll) for signalling the acquisition of the transmission right transmitted by the PC is received, until the NAV elapses or a signal (e.g., a data frame including CF-end) broadcasting the end of the CFP in the BSS is received. Note that, because no packet collision occurs in the same BSS during the CFP period, each terminal apparatus does not take a random backoff time used for the DCF.

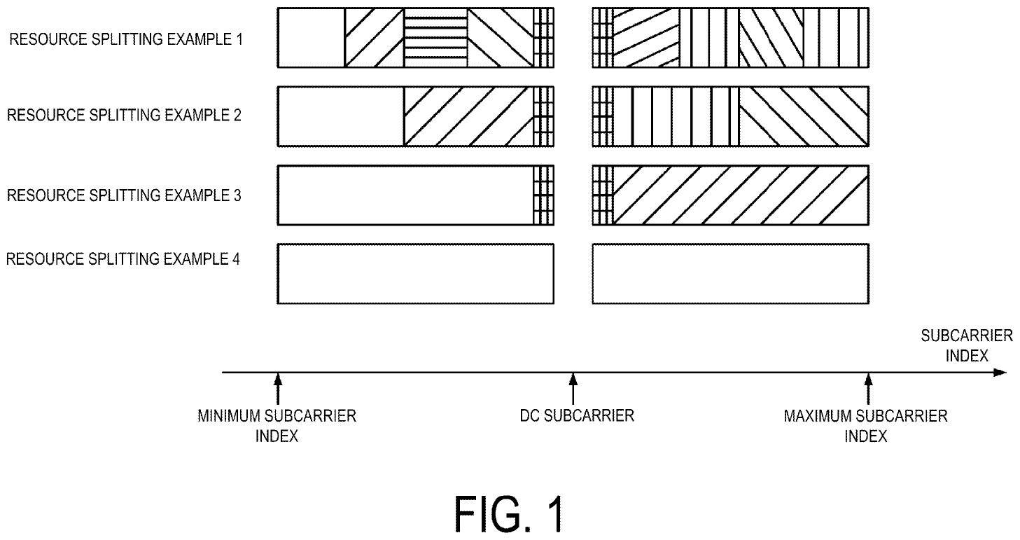

A radio medium can be split into multiple Resource units (RUs). FIG. 1 is a schematic diagram illustrating an example of a split state of a radio medium. In the resource splitting example 1, for example, a radio communication apparatus can split a frequency resource (subcarrier) that is a radio medium into nine RUs. Similarly, in the resource splitting example 2, the radio communication apparatus can split a subcarrier that is a radio medium into five RUs. It is a matter of course that the resource splitting example illustrated in FIG. 1 is just an example, and for example, each of the plurality of RUs can include a different number of subcarriers. The radio medium that is split into RUs can include not only a frequency resource but also a spatial resource. The radio communication apparatus (e.g., an AP) can transmit frames to multiple terminal apparatuses (e.g., multiple STAs) at the same time by mapping frames addressed to different terminal apparatuses to the respective RUs. An AP can describe information indicating a split state of the radio medium (Resource allocation information) as common control information in the PHY header of the frame transmitted by the AP itself. Moreover, the AP can describe information indicating an RU to which a frame addressed to each STA is mapped (resource unit assignment information) as unique control information in the PHY header of the frame transmitted by the AP itself.

Multiple terminal apparatuses (e.g., multiple STAs) can transmit frames at the same time by mapping and transmitting the frames to and in the respective RUs allocated to themselves. The multiple STAs can perform frame transmission after waiting for a prescribed period after receiving the frame including trigger information transmitted from the AP (Trigger frame (TF)). Each STA can recognize the RU allocated to the STA itself based on the information described in the TF. Each STA can acquire the RU through random access with reference to the TF.

The AP can allocate multiple RUs to one STA at the same time. The multiple RUs can include continuous subcarriers or can include discontinuous subcarriers. The AP can transmit one frame using multiple RUs allocated to one STA or can transmit multiple frames after allocating them to different RUs. At least one of the multiple frames can be a frame including common control information for multiple terminal apparatuses that transmit Resource allocation information.

One STA can be allocated multiple RUs by the AP. The STA can transmit one frame using the multiple allocated RUs. Also, the STA can use the multiple allocated RUs to transmit multiple frames allocated to different RUs. The multiple frames each can be a frame of a different frame type.

The AP can allocate multiple AIDs to one STA. The AP can allocate an RU to each of the multiple AIDs allocated to the one STA. The AP can transmit different frames using the respective RUs allocated to the multiple AIDs allocated to the one STA. The different frames each can be a frame of a different frame type.

One STA can be allocated multiple AIDs by the AP. The one STA can be allocated an RU with respect to each of the multiple allocated AIDs. The one STA recognizes all of the RUs allocated to the respective multiple AIDs allocated to the STA itself as RUs allocated to the STA and can transmit one frame using the multiple allocated RUs. In addition, the one STA can transmit multiple frames using the multiple allocated RUs. At this time, the multiple frames can be transmitted with information indicating the AIDs associated with the respective allocated RUs described therein. The AP can transmit different frames using the respective RUs allocated to the multiple AIDs allocated to the one STA. The different frames can be frames of different frame types.

Hereinafter, the base station apparatus and the terminal apparatuses may be collectively referred to as radio communication apparatuses or communication apparatuses. Information exchanged in a case that a certain radio communication apparatus performs communication with another radio communication apparatus may also be referred to as data. In other words, radio communication apparatuses include a base station apparatus and a terminal apparatus.

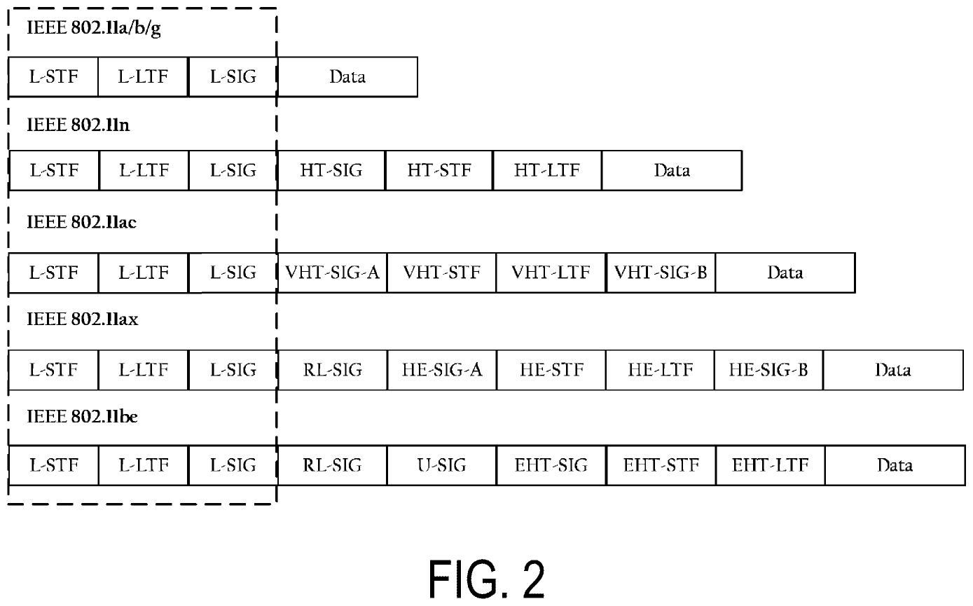

A radio communication apparatus includes any one of or both the function of transmitting a PPDU and a function of receiving a PPDU. FIG. 2 is a diagram illustrating an example of a configuration of the PPDU transmitted by the radio communication apparatus. A PPDU that is compliant with the IEEE 802.11 a/b/g standard includes L-STF, L-LTF, L-SIG, and a Data frame (a MAC Frame, a MAC frame, a payload, a data part, data, information bits, and the like). A PPDU that is compliant with the IEEE 802.11n standard includes L-STF, L-LTF, L-SIG, HT-SIG, HT-STF, HT-LTF, and a Data frame. A PPDU that is compliant with the IEEE 802.11 ac standard includes some or all of L-STF, L-LTF, L-SIG, VHT-SIG-A, VHT-STF, VHT-LTF, VHT-SIG-B, and a MAC frame. The PPDU in the IEEE 802.1 lax standard includes some or all of L-STF, L-LTF, L-SIG, RL-SIG in which L-SIG is temporally repeated, HE-SIG-A, HE-STF, HE-LTF, HE-SIG-B, and a Data frame. A PPDU studied in the IEEE 802.11be standard includes some or all of L-STF, L-LTF, L-SIG, RL-SIG, U-SIG, EHT-SIG, EHT-STF, HET-LTF, and a Data frame.

L-STF, L-LTF, and L-SIG surrounded by the dotted line in FIG. 2 are configurations commonly used in the IEEE 802.11 standard (hereinafter, L-STF, L-LTF, and L-SIG may also be collectively referred to as an L-header). For example, a radio communication apparatus that is compliant with the IEEE 802.11a/b/g standard can appropriately receive an L-header inside a PPDU that is compliant with the IEEE 802.11n/ac standard. The radio communication apparatus that is compliant with the IEEE 802 11 a/b/g standard can receive the PPDU that is compliant with the IEEE 802 11n/ac standard while regarding it as a PPDU that is compliant with the IEEE 802.11a/b/g standard.

However, because the radio communication apparatus that is compliant with the IEEE 802.11a/b/g standard cannot demodulate the PPDU that is compliant with the IEEE 802.11 n/ac standard following the L-header, it is not possible to demodulate information about a Transmitter Address (TA), a Receiver Address (RA), and a Duration/ID field used for configuring a NAV.

As a method for the radio communication apparatus that is compliant with the IEEE 802.11 a/b/g standard to appropriately configure the NAV (or perform a receiving operation for a predetermined period), IEEE 802.11 defines a method of inserting Duration information to the L-SIG. Information about a transmission speed in the L-SIG (a RATE field, an L-RATE field, an L-RATE, an L_DATARATE, and an L_DATARATE field) and information about a transmission period (a LENGTH field, an L-LENGTH field, and an L-LENGTH) are used by the radio communication apparatus that is compliant with the IEEE 802.11 a/b/g standard to appropriately configure a NAV.

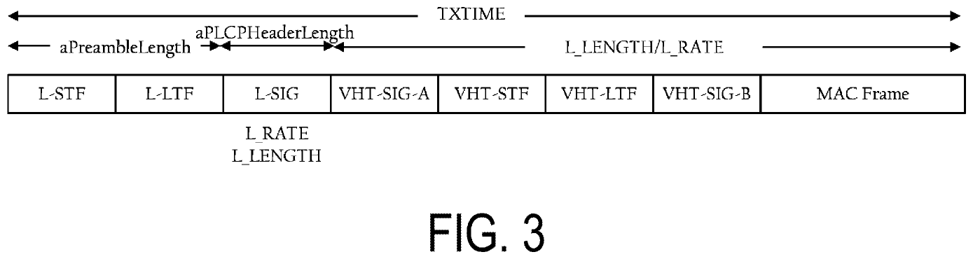

FIG. 3 is a diagram illustrating an example of a method of Duration information inserted into L-SIG. Although a PPDU configuration that is compliant with the IEEE 802.1 lac standard is illustrated as an example in FIG. 3, the PPDU configuration is not limited thereto. A PPDU configuration that is compliant with the IEEE 802.11n standard and a PPDU configuration that is compliant with the IEEE 802.11 ax standard may be employed. TXTAIE includes information about a length of a PPDU, aPreambleLength includes information about a length of a preamble (L-STF+L-LTF), and aPLCPHeaderLength includes information about a length of a PLCP header (L-SIG). L_LENGTH is calculated based on Signal Extension that is a virtual period configured for compatibility with the IEEE 802.11 standard, Nₒₚₛ related to L-RATE, aSymbolLength that is information about a period of one symbol (a symbol, an OFDM symbol, or the like), aPLCPServiceLength indicating the number of bits included in PLCP Service field, and aPLCPConvolutionalTailLength indicating the number of tail bits of a convolution code. The radio communication apparatus can calculate L_LENGTH and insert L_LENGTH into L-SIG. The radio communication apparatus can calculate L-SIG Duration. L-SIG Duration indicates information about a PPDU including L_LENGTH and information about a period that is the sum of periods of ACK and SIFS expected to be transmitted by the destination radio communication apparatus in response to the PPDU.

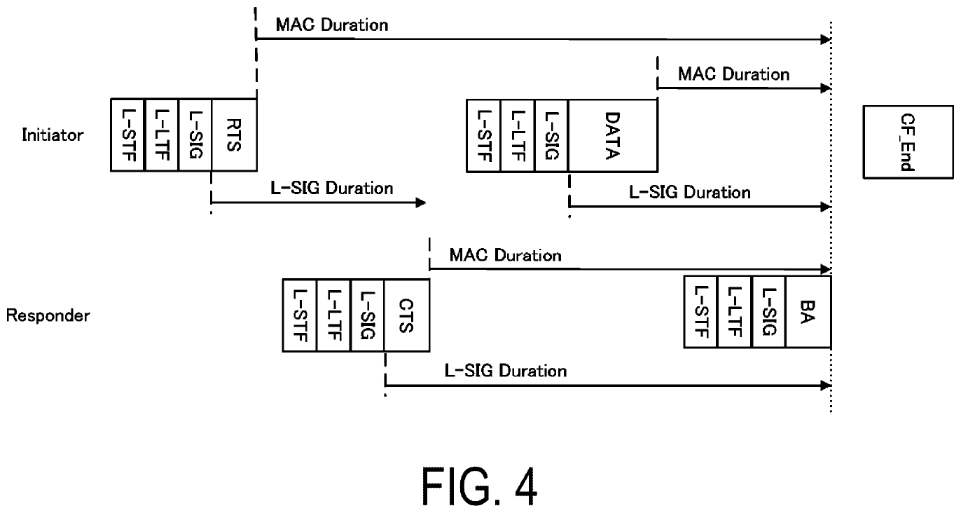

FIG. 4 is a diagram illustrating an example of L-SIG Duration in L-SIG TXOP Protection. DATA (a frame, a payload, data, and the like) include some of or both the MAC frame and the PLCP header. BA includes Block ACK or ACK. A PPDU includes L-STF, L-LTF, and L-SIG and can further include any one or more of DATA, BA, RTS, or CTS. Although L-SIG TXOP Protection using RTS/CTS is illustrated in the example illustrated in FIG. 4, CTS-to-Self may be used. Here, MAC Duration is a period indicated by a value of Duration/ID field. Initiator can transmit a CF_End frame for providing a notification regarding an end of the L-SIG TXOP Protection period.

Next, a method of identifying a BSS from a frame received by a radio communication apparatus will be described. In order for the radio communication apparatus to identify the BSS from the received frame, the radio communication apparatus that transmits a PPDU preferably inserts information (BSS color, BSS identification information, a value unique to the BSS) for identifying the BSS into the PPDU, and it is possible to describe information indicating BSS color in HE-SIG-A.

The radio communication apparatus can transmit L-SIG multiple times (L-SIG Repetition). For example, demodulation accuracy of L-SIG is improved by the radio communication apparatus on the reception side receiving L-SIG transmitted multiple times by using Maximum Ratio Combining (MRC). Moreover, in a case that reception of L-SIG is properly completed using MRC, the radio communication apparatus can interpret the PPDU including the L-SIG as a PPDU that is compliant with the IEEE 802.1 lax standard.

Even during the operation of receiving the PPDU, the radio communication apparatus can perform an operation of receiving part of a PPDU other than the corresponding PPDU (e.g., the preamble, L-STF, L-LTF, and the PLCP header prescribed by IEEE 802.11) (also referred to as a double-reception operation). In a case that a part of a PPDU other than the PPDU is detected during the operation of receiving the PPDU, the radio communication apparatus can update a part or an entirety of information about a destination address, a transmission source address, a PPDU, or a DATA period.

An ACK and a BA can also be referred to as a response (response frame). A probe response, an authentication response, and a connection response can also be referred to as a response.

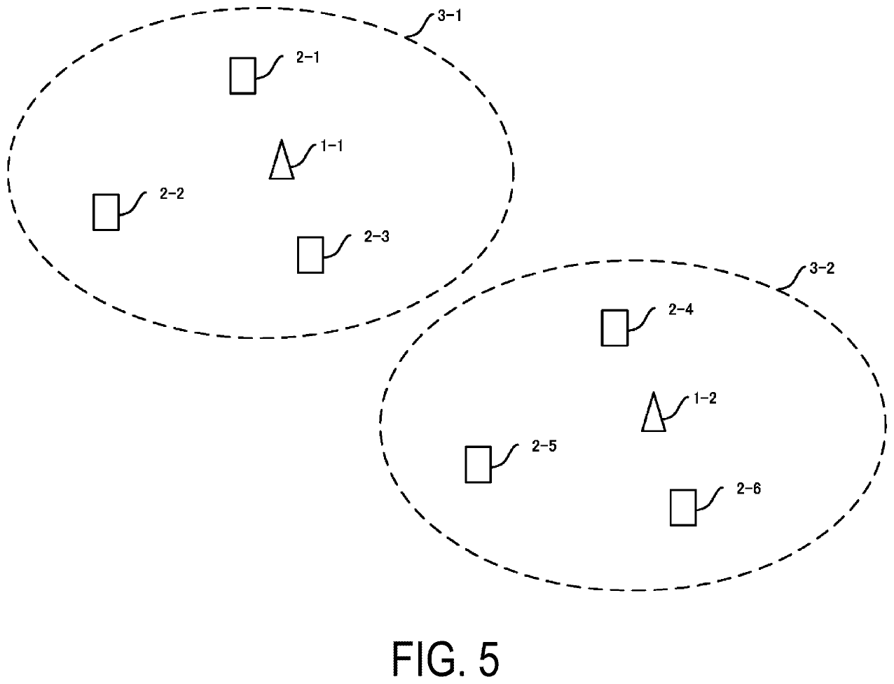

FIG. 5 is a diagram illustrating an example of a radio communication system according to the present embodiment. A radio communication system 3-1 includes a radio communication apparatus 1-1 and radio communication apparatuses 2-1 to 2-3. Note that the radio communication apparatus 1-1 may also be referred to as a base station apparatus 1-1, and the radio communication apparatuses 2-1 to 2-3 may also be referred to as terminal apparatuses 2-1 to 2-3. Each of the radio communication apparatuses 2-1 to 2-3 and each of the terminal apparatuses 2-1 to 2-3 may also be referred to as a radio communication apparatus 2A and a terminal apparatus 2A, respectively, as an apparatus connected to the radio communication apparatus 1-1. The radio communication apparatus 1-1 and the radio communication apparatus 2A are wirelessly connected and are in a state in which they can transmit and/or receive PPDUs to and from each other. The radio communication system according to the present embodiment may include a radio communication system 3-2 in addition to the radio communication system 3-1. The radio communication system 3-2 includes a radio communication apparatus 1-2 and radio communication apparatuses 2-4 to 2-6. Note that the radio communication apparatus 1-2 may also be referred to as a base station apparatus 1-2 and the radio communication apparatuses 2-4 to 2-6 may also be referred to as terminal apparatuses 2-4 to 2-6. Each of the radio communication apparatuses 2-4 to 2-6 and each of the terminal apparatuses 2-4 to 2-6 may also be referred to as a radio communication apparatus 2B and a terminal apparatus 2B, respectively, as an apparatus connected to the radio communication apparatus 1-2. Although the radio communication system 3-1 and the radio communication system 3-2 form different BSSs, this does not necessarily mean that Extended Service Sets (ESSs) are different. An ESS indicates a service set forming a Local Area Network (LAN). In other words, radio communication apparatuses belonging to the same ESS can be regarded as belonging to the same network from a higher layer. The BSSs are connected via a Distribution System (DS) and form an ESS. Note that each of the radio communication systems 3-1 and 3-2 can further include multiple radio communication apparatuses.

In FIG. 5, it is assumed that signals transmitted by the radio communication apparatus 2A reach the radio communication apparatus 1-1 and the radio communication apparatus 2B while the signals do not reach the radio communication apparatus 1-2 in the following description. In other words, in a case that the radio communication apparatus 2A transmits a signal using a certain channel, the radio communication apparatus 1-1 and the radio communication apparatus 2B determine that the channel is in the busy state, whereas the radio communication apparatus 1-2 determines that the channel is in the idle state. It is assumed that signals transmitted by the radio communication apparatus 2B arrive at the radio transmission apparatus 1-2 and the radio communication apparatus 2A, but do not arrive at the radio communication apparatus 1-1. In other words, in a case that the radio communication apparatus 2B transmits a signal using a certain channel, the radio communication apparatus 1-2 and the radio communication apparatus 2A determine that the channel is in the busy state, whereas the radio communication apparatus 1-1 determines that the channel is in the idle state.

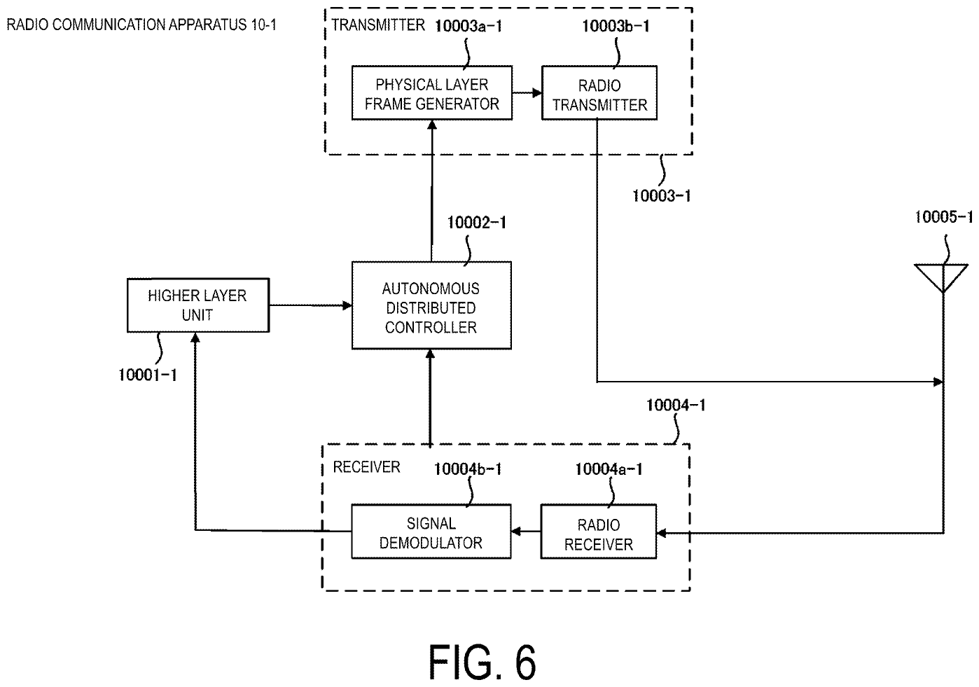

FIG. 6 is a diagram illustrating an example of an apparatus configuration of the radio communication apparatuses 1-1, 1-2, 2A, and 2B (hereinafter, collectively referred to as a radio communication apparatus 10-1 or a station apparatus 10-1 or also simply referred to as a station apparatus). The radio communication apparatus 10-1 includes a higher layer unit (higher layer processing step) 10001-1, an autonomous distributed controller (autonomous distributed control step) 10002-1, a transmitter (transmission step) 10003-1, a receiver (reception step) 10004-1, and an antenna unit 10005-1.

The higher layer unit 10001-1 is connected to another network and can notify the autonomous distributed controller 10002-1 of information about traffic. The information related to a traffic may be control information included in a management frame such as a beacon, for example, or may be measurement information reported by another radio communication apparatus to the radio communication apparatus. Moreover, the information may be control information included in a management frame or a control frame with the destination not limited (the information may be directed to the apparatus, may be directed to another apparatus, may be broadcasting, or may be multicasting).

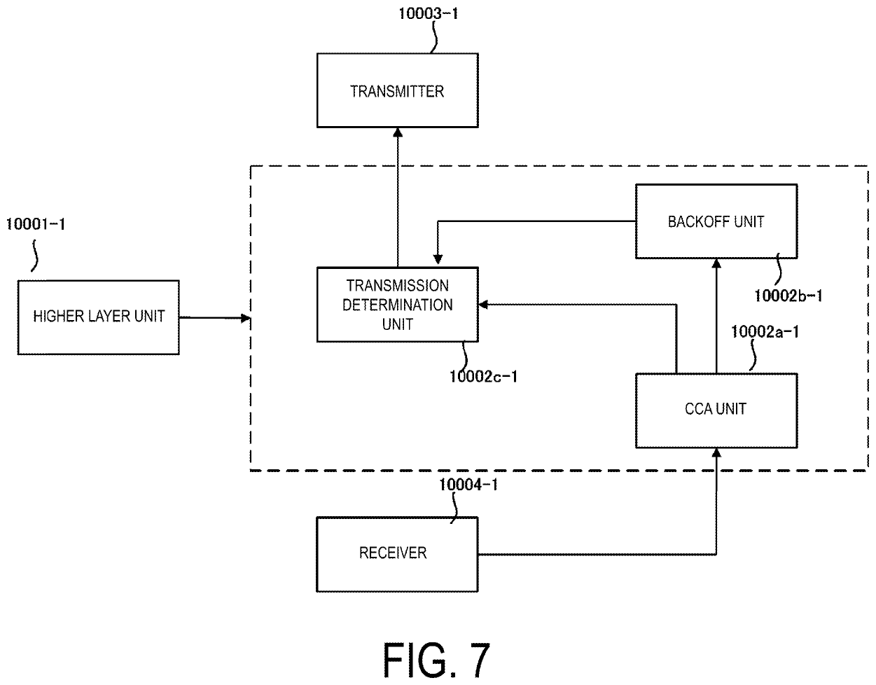

FIG. 7 is a diagram illustrating an example of an apparatus configuration of the autonomous distributed controller 10002-1. The controller 10002-1 includes a CCA unit (CCA step) 10002a-1, a backoff unit (backoff step) 10002b-1, and a transmission determination unit (transmission determination step) 10002c-1.

The CCA processor 10002a-1 can perform determination of a state of a radio resource (including determination between a busy state and an idle state) using any one of or both information related to reception signal power received via the radio resource and information related to the reception signal (including information after decoding) provided as a notification from the receiver 10004-1. The CCA unit 10002a-1 can notify the backoff unit 10002b-1 and the transmission determination unit 10002c-1 of the state determination information of the radio resources.

The backoff unit 10002b-1 can perform backoff using the state determination information of the radio resources. The backoff unit 10002b-1 has a function of generating a CW and counting down the CW. For example, the count-down of the CW is performed in a case that the state determination information of the radio resources indicates idle, and the count-down of the CW can be stopped in a case that the state determination information of the radio resources indicates busy. The backoff unit 10002b-1 can notify the transmission determination unit 10002c-1 of the value of the CW.

The transmission determination unit 10002c-1 performs transmission determination using either of or both the state determination information of the radio resources or/and the value of the CW. For example, the notification of transmission determination information can be provided to the transmitter 10003-1 in a case that the state determination information of the radio resources indicates idle and the value of the CW is zero. The notification of the transmission determination information can be provided to the transmitter 10003-1 in a case that the state determination information of the radio resources indicates idle.

The transmitter 10003-1 includes a physical layer frame generator (physical layer frame generation step) 10003a-1 and a radio transmitter (radio transmission step) 10003b-1. The physical layer frame generator 10003a-1 includes a function of generating a physical layer frame (hereinafter, also referred to as a frame or a PPDU) based on the transmission determination information provided as a notification from the transmission determination unit 10002c-1. The physical layer frame generator 10003a-1 performs error correction coding, modulation, precoding filter multiplication, and the like on transmission frames sent from the higher layer. The physical layer frame generator 10003a-1 notifies the radio transmitter 10003b-1 of the generated physical layer frame.

The frame generated by the physical layer frame generator 10003a-1 includes control information. The control information includes information indicating to which RU the data addressed to each radio communication apparatus is mapped (here, the RU including both frequency resources and spatial resources). The frame generated by the physical layer frame generator 10003a-1 includes a trigger frame for indicating, to the radio communication apparatus that is a destination terminal, frame transmission. The trigger frame includes information indicating the RU to be used by the radio communication apparatus that has received the indication for the frame transmission to transmit the frame.

The radio transmitter 10003b-1 converts the physical layer frame generated by the physical layer frame generator 10003a-1 into a signal in a Radio Frequency (RF) band to generate a radio frequency signal. Processing performed by the radio transmitter 10003b-1 includes digital-to-analog conversion, filtering, frequency conversion from a baseband to an RF band, and the like.

The receiver 10004-1 includes a radio receiver (radio reception step) 10004a-1 and a signal demodulator (signal demodulation step) 10004b-1. The receiver 10004-1 generates information about reception signal power from a signal in the RF band received by the antenna unit 10005-1. The receiver 10004-1 can notify the CCA unit 10002a-1 of the information about the reception signal power and the information about the reception signal.

The radio receiver 10004a-1 has a function of converting a signal in the RF band received by the antenna unit 10005-1 into a baseband signal and generating a physical layer signal (e.g., a physical layer frame). Processing performed by the radio receiver 10004a-1 includes frequency conversion processing from the RF band to the baseband, filtering, and analog-to-digital conversion.

The signal demodulator 10004b-1 has a function of demodulating a physical layer signal generated by the radio receiver 10004a-1. Processing performed by the signal demodulator 10004b-1 includes channel equalization, demapping, error correction decoding, and the like. The signal demodulator 10004b-1 can extract, from the physical layer signal, information included in the physical layer header, information included in the MAC header, and information included in the transmission frame, for example. The signal demodulator 10004b-1 can notify the higher layer unit 10001-1 of the extracted information. Note that the signal demodulator 10004b-1 can extract any one or all of the information included in the physical layer header, the information included in the MAC header, and the information included in the transmission frame.

The antenna unit 10005-1 includes a function of transmitting the radio frequency signal generated by the radio transmitter 10003b-1 to a radio space. Also, the antenna unit 10005-1 includes a function of receiving the radio frequency signal and passing the radio frequency signal to the radio receiver 10004a-1.

The radio communication apparatus 10-1 can cause radio communication apparatuses in the surroundings of the radio communication apparatus 10-1 to configure NAV corresponding to a period during which the radio communication apparatus uses a radio medium by describing information indicating the period in the PHY header or the MAC header of the frame to be transmitted. For example, the radio communication apparatus 10-1 can describe the information indicating the period in a Duration/ID field or a Length field of the frame to be transmitted. The NAV period configured to radio communication apparatuses in the surroundings of the radio communication apparatus will be referred to as a TXOP period (or simply TXOP) acquired by the radio communication apparatus 10-1. In addition, the radio communication apparatus 10-1 that has acquired the TXOP will be referred to as a TXOP acquirer (TXOP holder). The type of frame to be transmitted by the radio communication apparatus 10-1 to acquire TXOP is not limited to any frame type, and the frame may be a control frame (e.g., an RTS frame or a CTS-to-self frame) or may be a data frame.

The radio communication apparatus 10-1 that is a TXOP holder can transmit the frame to radio communication apparatuses other than the radio communication apparatus during the TXOP. In a case that the radio communication apparatus 1-1 is a TXOP holder, the radio communication apparatus 1-1 can transmit a frame to the radio communication apparatus 2A during the TXOP period. The radio communication apparatus 1-1 can indicate, to the radio communication apparatus 2A, a frame transmission addressed to the radio communication apparatus 1-1 during the TXOP period. The radio communication apparatus 1-1 can transmit, to the radio communication apparatus 2A, a trigger frame including information for indicating a frame transmission addressed to the radio communication apparatus 1-1 during the TXOP period.

The radio communication apparatus 1-1 may acquire a TXOP for the entire communication band (e.g., Operation bandwidth) in which frame transmission is likely to be performed, or may acquire a TXOP for a specific communication band (Band) such as a communication band in which frames are actually transmitted (e.g., Transmission bandwidth).

The radio communication apparatus that provides an indication for transmitting a frame in the TXOP period acquired by the radio communication apparatus 1-1 is not necessarily limited to radio communication apparatuses associated to the radio communication apparatus. For example, the radio communication apparatus can provide an indication for transmitting frames to radio communication apparatuses that are not associated to the radio communication apparatus in order to cause the radio communication apparatuses in the surroundings of the radio communication apparatus to transmit management frames such as a Reassociation frame or control frames such as an RTS/CTS frame.

Furthermore, TXOP in EDCA that is a data transmission method different from DCF will also be described. The IEEE 802.11e standard relates to the EDCA, and defines the TXOP from the perspective of QoS (Quality of Service) assurance for various services such as video transmission or VoIP. The services are roughly classified into four access categories, namely VOice (VO), VIdeo (VI), BestEffort (BE), and BacK ground (BK). In general, the services include VO, VI, BE, and BK, starting with the highest priority in this order. Each of the access categories has parameters including CWmin as a minimum value of CW, CWmax as a maximum value, Arbitration IFS (AIFS) as a type of IFS, and TXOP limit as an upper limit value of the transmission occasion, which are configured to give a difference in the priority. For example, it is possible to perform data transmission prioritized over the other access categories by configuration CWmin, CWmax, and AIFS of VO with the highest priority for the purpose of voice transmission equal to a relatively small value as compared with the other access categories. For example, for the VI, where the amount of transmission data is relatively large due to video transmission, the TXOP limit can be configured to be larger, so that the transmission occasion can be longer than the other access categories. In this manner, four parameter values of each of the access categories are adjusted for the purpose of QoS assurance in accordance with various services.

In the embodiments described below, the radio communication apparatus 1-1 (base station apparatus 1-1) performs transmission and the radio communication apparatus 2-1 (terminal apparatus 2-1) performs reception. However, an aspect of the present invention is not limited to this and includes a case where the radio communication apparatus 2-1 (terminal apparatus 2-1) performs transmission and the radio communication apparatus 1-1 (base station apparatus 1-1) performs reception. Note that the apparatus configurations of the radio communication apparatus 1-1 and the radio communication apparatus 2-1 are similar to the apparatus configuration example described using FIG. 6 and FIG. 7 unless particularly indicated otherwise.

The higher layer unit 10001-1 of the radio communication apparatus 1-1 according to the present embodiment transfers, to the transmitter 10003-1, an A-MPDU that is a payload of the MAC layer and into which one MPDU or two or more MPDUs are aggregated from the information bit sequence transferred to the MAC layer. The higher layer unit 10001-1 transfers the control information including the configuration of the retransmission scheme to the transmitter 10003-1. The configuration of the retransmission scheme is, for example, information indicating one of the ARQ or HARQ, or HARQ configuration information. The HARQ configuration information is information indicating whether the HARQ is configured and/or a HARQ scheme. The HARQ scheme includes Chase Combining (CC) or Incremental Redundancy (IR). In a case that the HARQ is not configured, the PHY layer determines that the ARQ is configured. In a case that the information bit sequence includes one MPDU, the configuration of the MPDU, the MPDU length, and the retransmission scheme is transferred to the transmitter in the lower layer. On the other hand, in the case that the information bit sequence includes A-MPDU, the A-MPDU and the A-MPDU length are transferred to the transmitter in the lower layer in a case that the configuration of the retransmission scheme indicates the ARQ. In a case that the configuration of the retransmission scheme indicates the HARQ, some or all of the A-MPDU, the A-MPDU length, each MPDU length, and the number of MPDUs are transferred to the transmitter in the lower layer. The MPDU may constitute one MSDU or an A-MSDU into which two or more MSDUs are aggregated. Note that in a case that the retransmission scheme is not indicated as the HARQ, the control information of the MAC layer of the higher layer unit 10001-1 does not necessarily include an additional information field for storing the MPDU length and the number of MPDUs.

The physical layer frame generator 10003a-1 of the radio communication apparatus 1-1 according to the present embodiment first generates a PSDU corresponding to a payload of the PHY layer, from the A-MPDU transferred by the higher layer unit 10001-1. The PSDU is assigned a PHY header to generate a PPDU for the transmission frame. The PHY header includes a PLCP preamble for synchronization detection, a PLCP header for determining a Modulation and Coding Scheme (MCS) in accordance with the received signal strength, control information notified by the MAC layer of the higher layer unit 10001-1, and an information field of a prescribed information bit length (coding block length) to be subjected to error correction coding corresponding to each information field in a case that the control information includes an additional information field for the MPDU length. Note that in a case that the MAC layer of the higher layer unit 10001-1 does not configure aggregation of MPDUs, the PHY header may store the prescribed information bit length in the information field.

For example, in error correction coding using a Low Density Parity Check (LDPC) of the IEEE 802.11 standard, a generation matrix is first obtained from a low-density parity check matrix, and parity bits are generated that are calculated from a matrix product of the generation matrix and information bits. Next, the parity bit is assigned to the information bit sequence to form a codeword. Specifically, the physical layer frame generator 10003a-1 calculates a prescribed information bit length to be subjected to error correction coding based on the size of the parity check matrix configured in accordance with the coding rate of the MCS. Note that an information bit sequence used for LDPC coding is also referred to as an LDPC information block, and a bit sequence obtained by LDPC-coding an LDPC information block is also referred to as an LDPC codeword block.

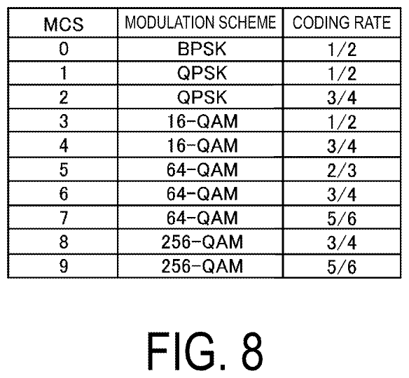

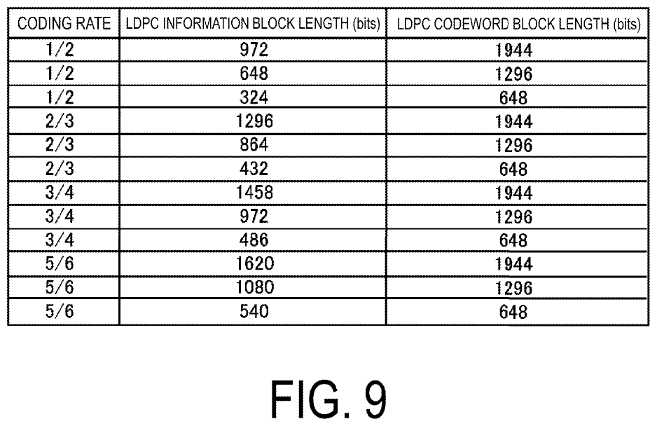

FIG. 8 illustrates an example of association between the MCS and the modulation scheme and the coding rate. For example, in a case that the MCS is 1, the modulation scheme is QPSK and the coding rate is ½, and in a case that the MCS is 4, the modulation scheme is 16QAM and the coding rate is ¾. FIG. 9 illustrates an example of association between the coding rate and an LDPC information block length and an LDPC codeword block length. In a case that the LDPC codeword block length is multiplied by the coding rate, the LDPC information block length is obtained. For example, in a case that the coding rate is ½, candidates of (LDPC information block length, LDPC codeword block length) are (972, 1944), (648, 1296), and (324, 648). Note that the LDPC information block length and the LDPC codeword block length are predefined values, and may be different from the transmitted information block length and codeword block length.

Description will be given of an example of a procedure in which the physical layer frame generator 10003a-1 divides the PSDU (A-MPDU) into information blocks in a case that the configuration of the retransmission scheme indicates ARQ. The LDPC codeword block length is determined by a coded bit length (also referred to as a first coded bit length) calculated based on at least the PSDU length (A-MPDU length) and the coding rate. For example, in the example of FIG. 9, in a case that the first coded bit length is 648 bits or less, the LDPC codeword block length (L_{CW}) is 648 bits. Next, in a case that the first coded bit length is greater than 648 bits and 1296 bits or less, the LDPC codeword block length is 1296 bits. In a case that the first coded bit length is greater than 1296 bits and 1944 bits or less, the LDPC codeword block length is 1944 bits. In a case that the first coded bit length is 1944 bits or less, the number of LDPC codeword blocks (N_{CW}) is 1. In a case that the first coded bit length is greater than 1944 bits and 2592 bits or less, the LDPC codeword block length is 1296 bits and the number of LDPC codeword blocks is 2. In a case that the LDPC codeword block length is larger than 2592 bits, the LDPC codeword block length is 1944 bits, and the number of LDPC codeword blocks can be calculated as ceil (first coded bit length/1944) from the first coded bit length and 1944 bits corresponding to the LDPC codeword block length. Note that ceil (x) is a ceiling function and represents the minimum integer equal to or greater than x.

In a case that N_{CW}*L_{CW}*R is different from the PSDU length, shortening processing is performed. Note that R represents the coding rate. The difference between N_{CW}*L_{CW}*R and the PSDU length is denoted by Nₛₕᵣₜ. Nₛₕᵣₜ is equally distributed among the information blocks. In other words, the shortening bit N_{shblk} of each information block is floor (Nₛₕᵣₜ/N_{CW}). However, floor (x) is a floor function and represents the maximum integer less than or equal to x. Note that the first Nₛₕᵣₜ mod N_{CW} block includes one more shortening bit than the other blocks. However, mod represents a remainder. In the shortening processing, N_{shblk} bits (or N_{shblk}+1) bits are added to the information block to generate an LDPC information block. Accordingly, the PSDU is divided into information blocks in consideration of the shortening processing. The LDPC information block is LDPC-coded to generate an LDPC codeword block, but the shortening bits are discarded.

In a case that N_{CW}*L_{CW} and (first coded bit length+Nₛₕᵣₜ) are different from each other, puncturing processing is performed to discard (decimate) parity bits. The difference between N_{CW}*L_{CW} and (first coded bit length+Nₛₕᵣₜ) is represented by N_{punc}. N_{punc} is equally distributed among the codeword blocks. In other words, the puncturing bit N_{pcblk} of each codeword block is floor (N_{punc}/N_{CW}). Note that the first N_{punc} mod N_{CW} block includes one more puncturing bit than the other blocks. In the puncturing processing, the last N_{pcblk} bits (or N_{pcblk}+1 bits) of the LDPC codeword block are discarded. The shortening processing and the puncturing processing generate a codeword block to be transmitted.

Note that in a case that a configuration of the retransmission scheme indicates a HARQ or in a case that the HARQ scheme indicates IR, the physical layer frame generator 10003a-1 encodes the LDPC information block at a mother coding rate, and then performs puncturing to generate a codeword block. Among the codeword blocks, a codeword block indicating initial transmission is also called a first codeword block, and a codeword block indicating retransmission is also called a second codeword block. Note that in the description of the present embodiment, a first codeword block length and a second codeword block length are the same but that an aspect of the present invention is not limited to this. Note that in the description of the following embodiment, the mother coding rate is ½ but that an aspect of the present invention is not limited to this. The mother coding rate may be, for example, ⅓, and may be equal to or lower than the coding rate indicated by the MCS. Note that a parity bit obtained by encoding the LDPC information block at the mother coding rate is also referred to as a mother parity bit. An LDPC codeword block obtained by encoding the LDPC information block at the mother coding rate is also referred to as a mother codeword block. A different mother coding rate may be configured for each MCS.

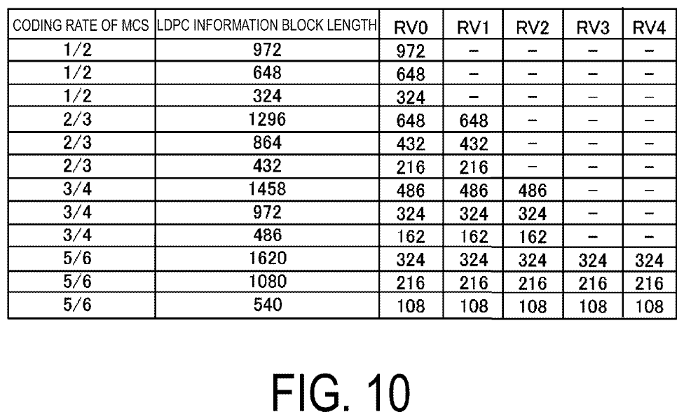

FIG. 10 illustrates an example in a case of the same LDPC information block length as that in FIG. 9. Note that the numerical values illustrated in FIG. 10 are examples. In the example of FIG. 10, first, the LDPC information block length is encoded at a mother coding rate of ½ using a parity check matrix based on the LDPC information block length. Then, based on the coding rate indicated by the MCS, the mother parity bits are divided into one or multiple parity blocks. For example, in a case that the coding rate indicated by the MCS is ½, the number of parity blocks is one. In a case that the coding rate indicated by the MCS is ⅔, the number of parity blocks is two. In a case that the coding rate indicated by the MCS is ¾, the number of parity blocks is three. In a case that the coding rate indicated by the MCS is ⅚, the number of parity blocks is five. In the example of FIG. 10, the first codeword block or the second codeword block is generated from the LDPC information block and one parity block. Note that in the example of FIG. 10, the first codeword length and the second codeword length are the same as those in a case that the HARQ configuration indicates the ARQ. The number of the parity block is associated with a Redundancy Version (RV). Note that RV0 to RV4 in the figure indicate that the RV is respectively 0, 1, 2, 3, and 4. Note that the value of the RV can also be interpreted as the number of retransmissions. In other words, RV0 can indicate the initial transmission, RV1 can indicate the first retransmission (second transmission), . . . , and RV4 can indicate the fourth retransmission (fifth transmission). The number of retransmissions and the value of the RV need not match. For example, RV0 can indicate the initial transmission, RV2 can indicate the first retransmission (second transmission), RV4 can indicate the second retransmission (third transmission), RV1 can indicate the third retransmission (fourth transmission), and RV3 can indicate the fourth retransmission (fifth transmission). Not all RVs need be transmitted. For example, only RV0 may be transmitted in either the initial transmission or the retransmission, or RV0 and RV3 may be alternately transmitted for each retransmission. The number of RVs (the number of parity blocks) is also referred to as Nᵣᵥ. For example, N, =1 at a coding rate of ½, N, =2 at a coding rate of ⅔, N, =3 at a coding rate of ¾, and N, =5 at a coding rate of ⅚. N, transmissions make the coding rate resulting from HARQ combining equal to the mother coding rate. The RV may be associated with the number of retransmissions. For example, RV0 is transmitted in the initial transmission (the number of retransmissions is 0), and RVx is transmitted in the n-th retransmission. Note that n is an integer of 0 or more, and x=n mod Nᵣᵥ. Note that mod represents a remainder. In this case, the first codeword block includes the LDPC information block and the parity block of RV0, and the second codeword block includes the LDPC information block and the parity block of the RV other than RV0. Note that in a communication environment such as a wireless LAN in which random access is performed, a packet collision may significantly degrade communication quality or prevent even reception to disable demodulation or decoding. In a case that packet collision occurs in the initial transmission, decoding fails however good the communication quality is, unless the second codeword block includes sufficient information bits. In the example of FIG. 10, the second codeword block includes the LDPC information block, and thus even in a case that the retransmission signal is independently received, the retransmission signal can be decoded. In a case that a parity block is transmitted that has an RV value varying between the initial transmission and the retransmission, and the receiving side performs HARQ combining, the coding rate decreases, thus improving the error correction capability.

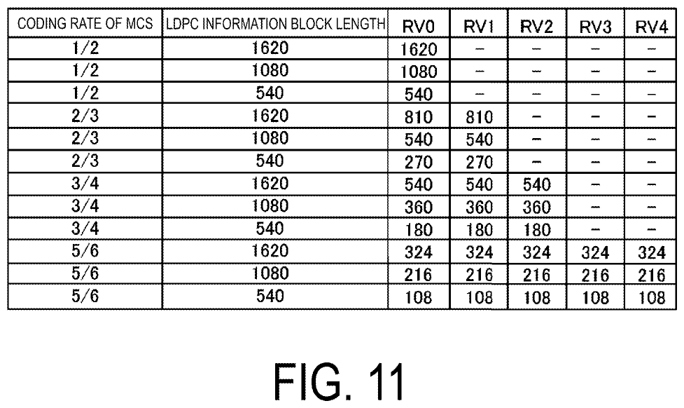

FIG. 11 is an example in which the LDPC information block length does not change depending on the coding rate indicated by the MCS. Therefore, in LDPC coding, a parity check matrix is used that has a mother coding rate of ½ for 1620 bits, 1080 bits, or 540 bits, which correspond to the LDPC information block length. As in the example of FIG. 10, the mother parity bits are divided into one or multiple parity blocks in association with the redundancy version, based on the coding rate indicated by the MCS. The LDPC codeword is generated from the LDPC information block and one parity block, in the example of FIG. 11, the LDPC codeword length changes depending on the coding rate indicated by the MCS. For example, in a case that the LDPC information block length is 1620 bits, and the coding rate indicated by the MCS is ½, ⅔, ¾, or ⅚, the corresponding first codeword block length is respectively 3240 bits, 2430 bits, 2160 bits, or 1944 bits. Also in the example of FIG. 11, the second codeword block includes the LDPC information block as in the case of the example of FIG. 10. Accordingly, even in a case that the retransmission signal is independently received, the retransmission signal can be decoded. In a case that a parity block is transmitted that has an RV value varying between the initial transmission and the retransmission, and the receiving side performs HARQ combining, the coding rate decreases, thus improving the error correction capability.

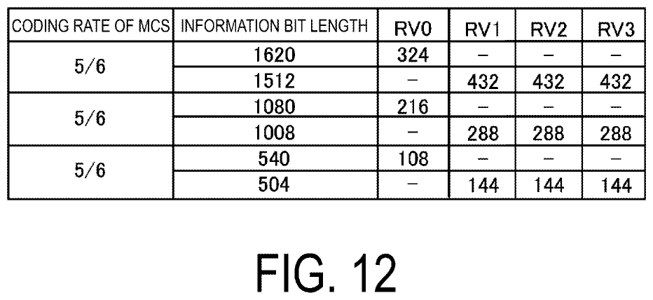

Although it depends on the coding rate, the LDPC can be decoded even in a case that a small number of information bits are decimated from the codeword. This can be utilized to reduce Nᵣᵥ. FIG. 12 illustrates an example in which Nᵣ is reduced to 4 in a case that the MCS has a coding rate of ⅚. For the initial transmission (RV0), the LDPC information block length is 1620 bits, 1080 bits, or 540 bits, and the information bit length included in the first codeword block is the same as the LDPC information block length. The parity block length included in the first codeword block is 324 bits, 216 bits, or 108 bits. For the retransmissions (from RV1 to RV3), the information bit length included in the second codeword block is 1512 bits, 1008 bits, or 504 bits, and is less than the LDPC information block length. The parity block length included in the first codeword block is 432 bits, 288 bits, or 144 bits, and is greater than the parity block length included in the first codeword block. Note that the second codeword block can be decoded even in a case that the retransmission signal is independently received. The reduced N, allows the mother coding rate to be achieved with a smaller number of retransmissions.

Note that in a case that all the parity bits not transmitted in the initial transmission are transmitted in the retransmission, the mother coding rate can be achieved. For example, in a case that the coding rate indicated by the MCS is ¾, the first codeword block includes 1458 information bits and 486 parity bits, and the second codeword block includes 972 information bits and 972 parity bits. In a case that the coding rate indicated by the MCS is ⅚, the first codeword block includes 1620 information bits and 324 parity bits, and the second codeword block includes 648 information bits and 1296 parity bits.

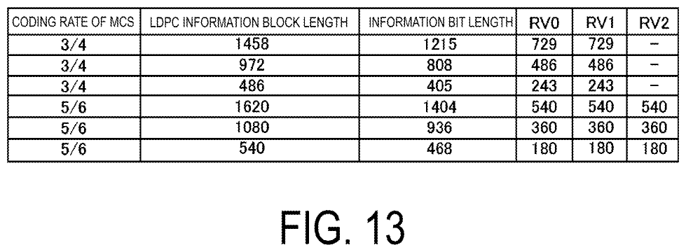

FIG. 13 is an example in which information bits are decimated in all the RVs to reduce Nᵣᵥ. In a case that the coding rate indicated by the MCS is ¾, the LDPC information block length is 1458 bits, 972 bits, or 486 bits. N, can be reduced to 2 by decimating the information bits transmitted at the time of the initial transmission or retransmission to 1215 bits, 808 bits, or 405 bits, to increase the parity block length. In a case that the coding rate indicated by the MCS is ⅚, the LDPC information block length is 1620 bits, 1080 bits, or 540 bits. N, can be reduced to 3 by decimating the information bits transmitted at the time of the initial transmission or retransmission to 1404 bits, 936 bits, or 468 bits, to increase the parity block length. Note that the information bits to be transmitted may be obtained by decimating front or rear bits of the LDPC information block. Whether to decimate the front or rear bits of the LDPC information block may vary depending on the value of the RV. For example, in a case that the RV is an even number (in the case of RV0 or RV2), the information bits to be transmitted can be obtained by decimating the rear bits of the LDPC information block, and in a case that the RV is an odd number (in the case of RV1), the information bits to be transmitted can be obtained by decimating the front bits of the LDPC information block.

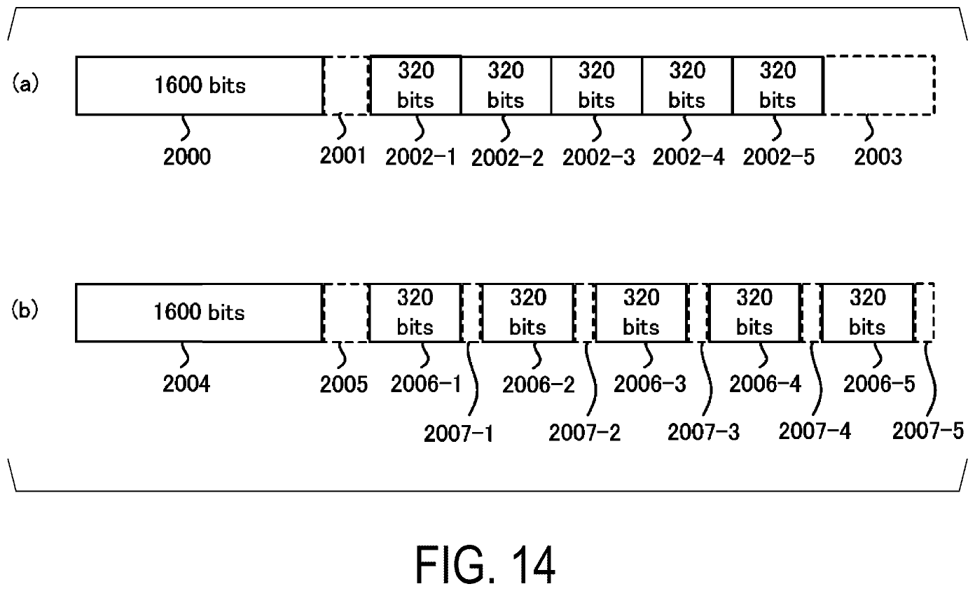

As described above, the LDPC code may require shortening processing and/or puncturing processing. FIG. 14 illustrates an example in which the coding rate indicated by the MCS is ⅚, the LDPC information block includes 1600 information bits and 20 shortening bits, and N, =5. In a case that the configuration of the retransmission scheme indicates the HARQ or that the HARQ scheme indicates IR, FIGS. 14(a) and 14(b) illustrate two possible procedures of the shortening processing and/or the puncturing processing. In FIG. 14(a), the mother codeword block includes 1600 information bits 2000, 20 shortening bits 2001, parity blocks 2002-1 to 2002-5 of 320 bits, and 20 puncturing bits 2003. The parity bits of the mother codeword block are divided into parity blocks 2002-1 to 2002-5 after the puncturing bits 2003 are decimated. In FIG. 14(b), the mother codeword block includes 1600 information bits 2004, 20 shortening bits 2005, parity blocks 2006-1 to 2006-5 of 320 bits, and 4 puncturing bits 2007-1 to 2007-5. The parity bits of the mother codeword block are divided into blocks of 324 bits. Decimating 4 puncturing bits from this block results in generation of a parity block of 320 bits. In the example of FIG. 14(b), 4 bits obtained by dividing 20 puncturing bits by N, =5 are the puncturing bits in each block. Note that the description of FIG. 14 employs the coding rate of ⅚ indicated by the MCS but that an aspect of the present invention is not limited to this and is similarly applicable at any other coding rate. An aspect of the present invention is similarly applicable in a case that N, is reduced to 4 at the coding rate of ⅚ indicated by the MCS. In this case, since N, =4, each block includes 5 puncturing bits.

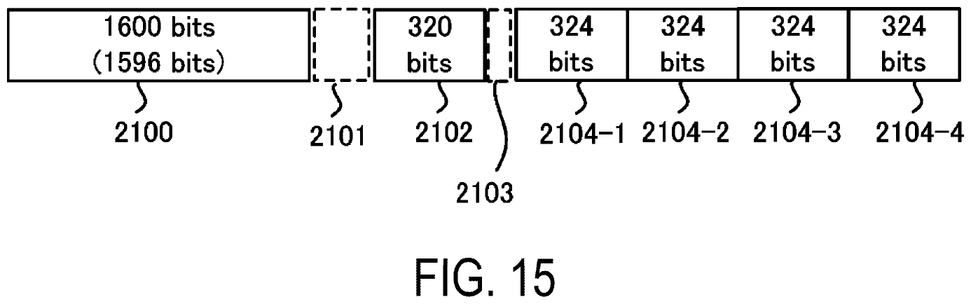

FIG. 15 illustrates an example in which for the retransmission, the information bits are punctured with no parity bits punctured. Here, the description employs, as examples, the coding rate of ⅚ indicated by the MCS and N, =5. In the example of FIG. 15, the mother codeword block includes 1600 information bits 2100, 20 shortening bits 2101, a parity block of 324 bits in the initial transmission (RV0), and parity blocks 2104-1 to 2104-4 of 324 bits in the retransmissions (RV1 to RV4). The parity block in the initial transmission includes 320 initial-transmission parity bits 2102 and 4 initial-transmission puncturing bits 2103. At the time of the retransmission, puncturing performed on the parity block in the initial transmission is performed on the information bits, and thus the information bit length of the second codeword block is 1596 bits. In a case that the parity block of RV0 is transmitted in the retransmission, the puncturing bits 2103 may be transmitted with the information bits punctured. At this time, the second codeword block includes 1596 information bits and 324 parity bits.

Note that as in the examples of FIG. 12 and FIG. 13, in a case that the information bits are decimated by a method other than shortening, the information bits may be decimated from the bits resulting from exclusion of the shortening bits.

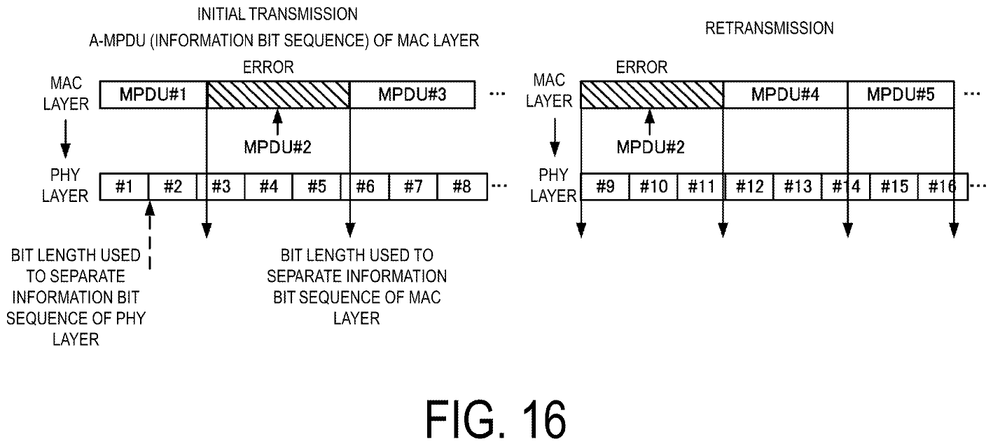

FIG. 16 is a schematic diagram illustrating an example of blocking processing executed by the physical layer frame generator 10003a-1 in a case that the configuration of the retransmission scheme indicates the ARQ. The physical layer frame generator 10003a-1 in the figure generates a transmission frame by dividing the PSDU into information blocks corresponding to multiple payloads by using the prescribed information bit length determined by the MCS included in the PHY header, and performing error correction coding on each information block. Note that an information block subjected to error correction coding is also referred to as a codeword block. In the blocking processing in the figure, the prescribed bit length used by the MAC layer to separate the information bit sequence into PSDUs may not match an allocation of multiple prescribed bit lengths used by the PHY layer to separate the information bit sequence into PSDUs. In other words, the physical layer frame generator 10003a-1 permits allows each information block to include two or more MPDUs. Each of block #3 and block #6 in FIG. 11 includes two or more MPDUs, and block #3 stores a part of the information bit sequence included in MPDUs #1 and #2 and block #6 stores a part of the information bit sequence included in MPDUs #2 and #3. Note that in this example, the MAC layer of the higher layer unit 10001-1, having received the Block ACK in the transmission frame, retransmits MPDU #2 because an error is detected in MPDU #2. In a case that MPDU #2 is retransmitted, the PHY layer blocks and transmits the PSDU. However, in a case that a block of the PHY layer includes multiple MPDUs, the PSDU may be divided into blocks different from those used at the time of initial transmission, and in this case, different codeword blocks are transmitted. In this case, the reception side fails to combine the initially transmitted MPDU #2 and the retransmitted MPDU #2.

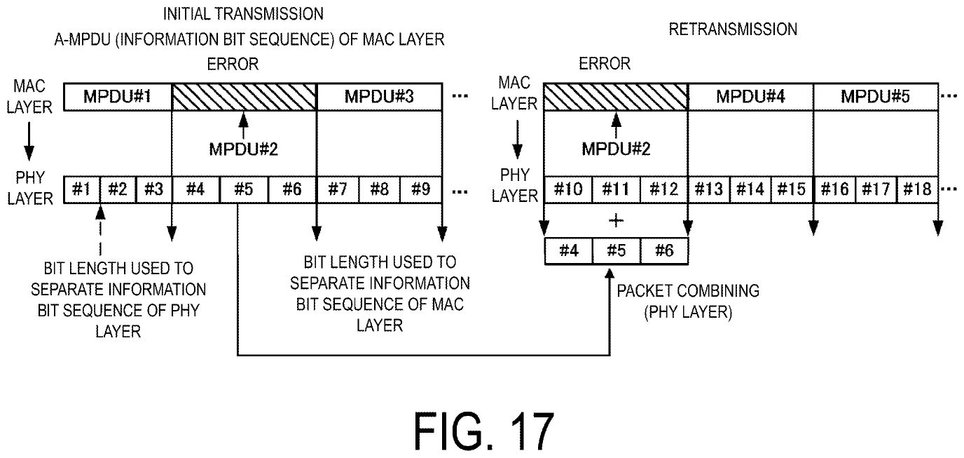

FIG. 17 is a schematic diagram illustrating an example of blocking processing performed by the physical layer frame generator 10003a-1 in a case that the control information of the MAC layer includes the information field of the MPDU length (in a case that the configuration of the retransmission scheme indicates the HARQ). The physical layer frame generator 10003a-1 in the figure divides each of the MPDUs constituting the PSDU into multiple information blocks based on the MPDU length of the control information in addition to the prescribed information bit length specified by the MCS included in the PHY header. The physical layer frame generator 10003a-1 calculates and stores the information block length in the information field of the header. In a case that an integer multiple of the information block length is the MPDU length, the number of information blocks may be stored in the PHY header. Subsequently, each information block is subjected to error correction coding to generate a transmission frame. In the blocking processing in the figure, one MPDU includes one or more information blocks. In other words, the physical layer frame generator 10003a-1 is not allowed to include two or more MPDUs in each block. Blocks #4 to #6 in the figure each store an information bit sequence of MPDU #2. Note that in this example, the MAC layer of the higher layer unit 10001-1, having received the Block ACK in the transmission frame, retransmits MPDU #2 because an error is detected in MPDU #2. Since each MPDU is divided into information blocks, the same codeword block as that used at the time of the initial transmission can be transmitted at the time of retransmission. In this case, the initially transmitted MPDU #2 is combined with the retransmitted MPDU #2 to enable reception quality to be improved.

In a case that the configuration of the retransmission scheme indicates the HARQ, the LDPC codeword block length is determined by a coded bit length (also referred to as a second coded bit length) calculated based on at least the MPDU length and the coding rate of the MCS. In a case that the MPDU length varies with each MPDU, the second coded bit length is calculated for each MPDU. For example, in a case that the second coded bit length is 648 bits or less, the LDPC codeword block length is 648 bits. In a case that the second coded bit length is greater than 648 bits and 1296 bits or less, the LDPC codeword block length is 1296 bits. In a case that the second coded bit length is greater than 1296 bits and 1944 bits or less, the LDPC codeword block length is 1944 bits. Note that in a case that the second coded bit length is 1944 bits or less, the number of LDPC codeword blocks is 1. In a case that the second coded bit length is greater than 1944 bits and 2592 bits or less, the LDPC codeword block length is 1296 bits and the number of LDPC codeword blocks is 2. In a case that the LDPC codeword block length is larger than 2592 bits, the LDPC codeword block length is 1944 bits, and the number of LDPC codeword blocks can be calculated as ceil (second coded bit length/1944) from the second coded bit length and 1944 bits corresponding to the LDPC codeword block length.

Note that as illustrated in FIG. 11, in a case that the LDPC codeword block length changes depending on the coding rate of the MCS, the LDPC codeword length is determined at least by the second coded bit length and the coding rate of the MCS. For example, as illustrated in FIG. 11, one coding rate of the MCS is assumed to correspond to three LDPC information block lengths of a first LDPC information block length, a second LDPC information block length, and a third LDPC information block length. Note that the first LDPC information block length <the second LDPC information block length <the third LDPC information block length. For example, in FIG. 11, in a case that the MCS has a coding rate of ½, the first LDPC information block length is 540 bits, the second LDPC information block length is 1080 bits, and the third LDPC information block length is 1620 bits. The LDPC codeword block length for the first LDPC information block length is also referred to as a first LDPC codeword block length, the LDPC codeword block length for the second LDPC information block length is also referred to as a second LDPC codeword block length, and the LDPC codeword block length for the third LDPC information block length is also referred to as a third LDPC codeword block length. At this time, in a case that the second coded bit length is equal to or less than the first LDPC codeword block length, the LDPC codeword block length corresponds to the first LDPC codeword block length. In a case that the second coded bit length is greater than the first LDPC codeword block length and is equal to or less than the second LDPC codeword block length, the LDPC codeword block length corresponds to the second LDPC codeword block length. In a case that the second coded bit length is greater than the second LDPC codeword block length and is equal to or less than the third LDPC codeword block, the LDPC codeword block length corresponds to the third LDPC codeword block length. Note that in a case that the LDPC codeword block length is equal to or less than the third LDPC codeword block length, the number of LDPC codeword blocks is 1. In a case that the second LDPC coded bit length is greater than the third LDPC codeword block length and is equal to or less than twice the second LDPC codeword block length, the LDPC codeword block length corresponds to the second LDPC codeword block length and the number of LDPC codeword blocks is 2. In a case that the LDPC codeword block length is greater than twice the second LDPC codeword block length, the LDPC codeword block length corresponds to the third LDPC codeword block length, and the number of LDPC codeword blocks is calculated from the second coded bit length and the third LDPC codeword block length as ceil (second coded bit length/third LDPC codeword block length).

In a case that the configuration of the retransmission scheme indicates the HARQ, the shortening processing is performed for each MPDU. In a case that N_{CW}*L_{CW}*R is different from the MPDU length, the shortening processing is performed. The difference between N_{CW}L_{CW}R and the MPDU length is represented by Nₛₕᵣₜ. Nₛₕᵣₜ is equally distributed among the information blocks. In other words, the shortening bit N_{shblk} of each information block is floor (Nₛₕᵣₜ/N_{CW}). Note that the first Nₛₕᵣₜ mod N_{CW} block includes one more shortening bit than the other blocks. However, mod represents a remainder. In the shortening processing, N_{shblk} bits (or N_{shblk}+1) bits are added to the information block to generate an LDPC information block. Accordingly, the PSDU is divided into information blocks in consideration of the shortening processing. The LDPC information block is LDPC-coded to generate an LDPC codeword block, but the shortening bits are discarded.

In a case that the configuration of the retransmission scheme indicates the HARQ, the puncturing processing is performed for each MPDU. In a case that N_{CW}*L_{CW} is different from (second coded bit length+Nₛₕᵣₜ), the puncturing processing is performed. The difference between N_{CW}*L_{CW} and (second coded bit length+Nₛₕᵣₜ) is represented by N_{punc}. N_{punc} is equally distributed among the codeword blocks. In other words, the puncturing bit N_{pcblk} of each codeword block is floor (N_{punc}/N_{CW}). Note that the first N_{punc} mod N_{CW} block includes one more puncturing bit than the other blocks. In the puncturing processing, the last N_{pcblk} bits (or N_{pcblk}+1 bits) of the LDPC codeword block are discarded. The shortening processing and the puncturing processing generate a codeword block to be transmitted.

On the other hand, in a case that the MAC-layer control information includes the information field of the MPDU length (in a case that the configuration of the retransmission scheme indicates the ARQ), the physical layer frame generator 10003a-1 according to the present embodiment can perform the blocking processing on the PSDU with the coded block length by referencing a table or a calculation formula that enables the coded block length to be calculated according to the MCS and the MPDU length.

Note that the coding method according to the present embodiment is not limited to the LDPC. For example, the transmission apparatus according to the present embodiment can also use a Binary Convolutional Code (BCC). At this time, the transmission apparatus can use BCC and the blocking processing method described above, that is, the blocking processing performed in a case that ARQ is configured and the blocking processing performed in a case that the HARQ is configured. For example, in a case that the HARQ is configured, the transmission apparatus can match the number of information bits included in the information block with the number of bits included in the MPDU. The transmission apparatus can match an integer multiple of the number of information bits included in the information block with the number of bits included in the MPDU.

The transmission apparatus according to the present embodiment can switch the blocking processing depending on the error correction coding method configured in the PHY layer. For example, in a case that BCC is configured as the error correction coding method, the transmission apparatus can perform the blocking processing assuming the ARQ, and in a case that LDPC is configured, the transmission apparatus can perform blocking processing assuming the HARQ. In a case that BCC is configured, the transmission apparatus may perform the blocking processing assuming the HARQ, and in a case that the LDPC is configured, the transmission apparatus may perform the blocking processing assuming the ARQ.

The table or calculation formula may include multiple MPDU length candidate values for each maximum MPDU size (e.g., 3895, 7991, 11454 bytes for 11 ac), and may store, in each of the MPDU lengths, a candidate value for a prescribed information bit length to be encoded for each MCS. For example, in a case that one MPDU length constituting the A-MPDU transferred from the higher layer unit 10001-1 according to the present embodiment is 3895 bytes or less, the transmitter can reference the table or the calculation formula to select a candidate value that is the same as the MPDU length of the MPDU or a candidate value that is closest to the MPDU length, and can sequentially acquire candidate values of the coded block length as indexes according to the MCS. The station apparatus, the access point, and the like according to the present embodiment can update the table or the calculation formula by a management frame such as a beacon frame, and can share the index of the coded block length.

In the blocking processing using the table and the calculation formula, the PHY header included in the transmission frame includes a PLCP preamble for performing synchronization detection, a PLCP header for determining the modulation and coding scheme (MCS) corresponding to the received signal strength, control information for notifying the ARQ/HARQ in the MAC layer of the higher layer unit 10001-1, and the index enabling the coded block length to be referenced.

In a case that the configuration of the retransmission scheme indicates the HARQ, the MPDU length and/or the MCS can be limited to prevent one information block from including the bits of multiple MPDUs. For example, the MPDU length is limited to an integer multiple of the LDPC information block length corresponding to an LDPC codeword block length of 1944 bits, and the use of the MCSs other than the MCS with the coding rate corresponding to a LDPC block length that is a divisor of the MPDU is limited. For example, in a case that multiple MPDUs of 1458 bytes are aggregated into a PSDU, since the MPDU length is divisible by LDPC information blocks corresponding to coding rates of ½, ⅔, and ¾, the result remains unchanged regardless of whether the PSDU is subjected to the blocking processing or each MPDU is subjected to the blocking processing. Accordingly, in a case that the configuration of the retransmission scheme indicates the HARQ and the MPDU length is 1458 bytes, by avoiding the use of MCS7 and MCS9 with a coding rate of ⅚ corresponding to the LDPC information block length by which the MPDU length is indivisible, HARQ combining can be performed on the reception side even in a case that the PSDU is subjected to the flocculation processing as in the case that the configuration of the retransmission scheme indicates the ARQ. Even in a case that the retransmission scheme is configured as the HARQ, the retransmission scheme may mean the ARQ in a case that a limited MCS is used. For example, in a case that MCS7 is applied for an MPDU length of 1458 bytes, the retransmission scheme may indicate the ARQ. In this case, even in a case that the configuration of the retransmission scheme indicates the HARQ, the radio communication apparatus 1-1 performs blocking processing on the PSDU and transmits the blocked PSDU.

The radio communication apparatus 1-1 according to the present embodiment indicates, as the ARQ/HARQ, the retransmission scheme included in the control information notified by the MAC layer of the higher layer unit 10001-1, allowing configuration indicating whether to assign the control information with information fields for the MPDU lengths constituting the A-MPDU. This allows switching between the blocking processing on the PSDU and the blocking processing on the MPDU according to the control information.

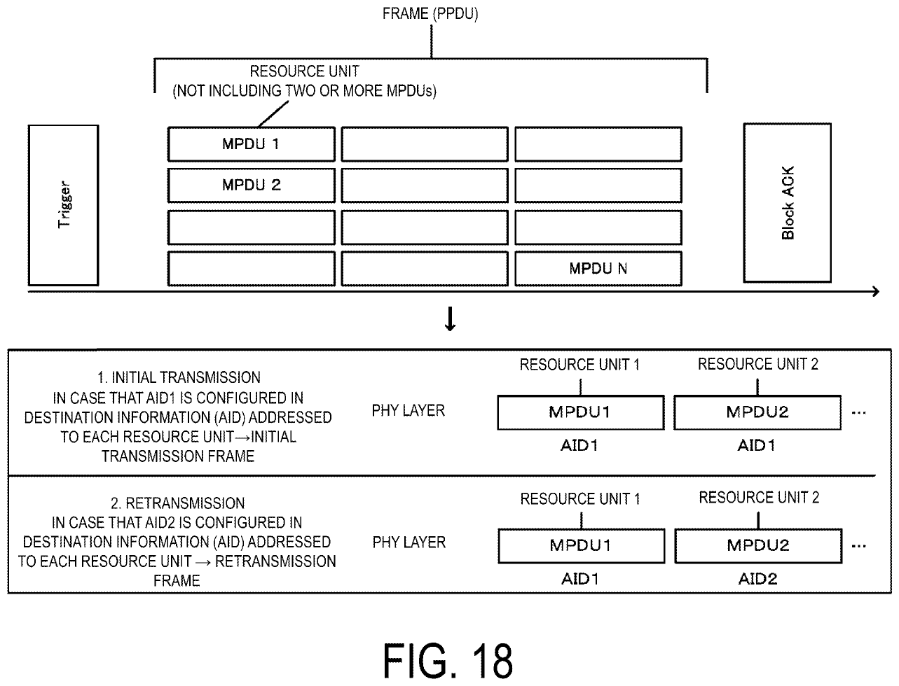

In connection with the radio communication apparatus according to the present embodiment as described above, FIG. 18 is a schematic diagram illustrating an example of control information related to a packet combining method of the PHY layer generated by the higher layer unit. First, the higher layer unit 10001-1 of the radio communication apparatus 1-1 according to the present embodiment generates an MPDU addressed to destination information (AID) from an information bit sequence transferred to the MAC layer, does not allow allocation of two or more MPDUs to a resource unit in a wireless channel, and distinguishes the MPDUs allocated to the resource unit from each other as a first MPDU and a second MPDU. Note that the first MPDU and the second MPDU are respectively corresponding to MPDU1 and MPDU2 in the figure. In the figure, the resource unit 1 to which MPDU1 is allocated is also referred to as a first resource unit, and the resource unit 2 to which MPDU2 is allocated is also referred to as a second resource unit. Next, in order to generate, in the MAC layer, control information related to the packet combining method of the PHY layer for the first MPDU and the second MPDU, the higher layer unit 10001-1 may assign multiple different AIDs to each of the first MPDU and the second MPDU and configure the HARQ for the AIDs. For example, in the figure, in a case that the transmission frame is initially transmitted, an AID 1 indicating an initial transmission frame is configured in the AID addressed to each resource unit, and in a case that the transmission frame is retransmitted, an AID 2 indicating a retransmission frame is configured in the AID addressed to each resource unit. This allows the HARQ to be configured in the retransmission frame corresponding to the AID 2. Note that the higher layer unit 10001-1 of the radio communication apparatus 1-1 according to the present embodiment does not limit the allocation to the MPDU for each of the resource units to the frequency direction regardless of the initial transmission or the retransmission, and can also perform the allocation in the time axis direction.

In other words, the higher layer unit 10001-1 of the radio communication apparatus 1-1 according to the present embodiment generates control information related to the packet combining method of the PHY layer including the method of allocating the first MPDU and the second MPDU of the MAC layer to the resource unit and the configuration of the AID and the HARQ assigned to each of the first MPDU and the second MPDU. The control information is transmitted to the PHY layer by the controller 10002-1 of the radio communication apparatus 1-1 according to the present embodiment.

Note that configuration/cancellation of the HARQ for the AID may be performed in a case that a request for an acknowledgement (ACK, block ACK, multi-STA block ACK) times out or the acknowledgement notifies the AIDs of the first MPDU and the second MPDU. The configuration/cancellation of the HARQ for the AID can also be performed by connection authentication/reconnection authentication (association/reassociation), respectively, and the AID of an authentication frame (authentication response) indicating whether the communication apparatus is authenticated may be used. The configuration/cancellation of the HARQ for the AID may be notified using the AID included in the management frame and the control frame.

Note that the control information does not limit the packet combining method based on the HARQ to anything. For example, the packet combining method may be chase combining in which the same packet is transmitted at the time of the initial transmission and at the time of the retransmission to allow the reception side to perform packet combining to improve the SNR of a received signal, or incremental redundancy combining in which at the time of the retransmission, a parity signal representing a redundant signal is added to improve an error correction decoding capability on the reception side. The frame generator allows the control information to include additional information required for the packet combining method.

The higher layer unit 10001-1 of the radio communication apparatus 1-1 according to the present embodiment may be capable of configuring either ARQ or HARQ. For example, in a case that the ARQ is configured in the higher layer unit, the radio communication apparatus 1-1 generates the AID 1. In a case that the HARQ is configured in the higher layer unit, the radio communication apparatus 1-1 generates the AID 1 or the AID 2. In a case that the HARQ is configured in the higher layer unit, multiple MPDUs are not allocated to one resource unit. In a case that the HARQ is configured, each MPDU or each resource unit is associated with the AID 1 or AID 2. The radio communication apparatus 1-1 associates the AID 1 with the MPDU or the resource unit in the case of the initial transmission, and associates the AID 1 or the AID 2 with the MPDU or the resource unit in the case of the retransmission.

The frame generator 10003a-1 of the radio communication apparatus 1-1 according to the present embodiment generates a PHY header based on the control information related to the packet combining method of the PHY layer transmitted by the controller 10002-1, and generates a PPDU including the PHY header, the first MPDU, and the second MPDU. FIG. 18 described above illustrates an example of overview of the PPDU. In other words, the PHY header includes a PLCP preamble for synchronization detection and a PLCP header for determining a Modulation and Coding Scheme (MCS) according to received signal strength, and in a case that the HARQ is added to the control information, information elements related to a packet combining method of the PHY layer such as the AID, modulation and coding scheme (MCS), coding scheme, RU allocation information, and RV for the first MPDU and the second MPDU can be included in the PLCP preamble or the PLCP header, and the information elements addressed to multiple station apparatuses can be included in the user-specific information field. For example, the information element may be included in the VHT-SIG-B field of the 11ac standard, the HE-SIG-B field of the 11ax standard, the EHT-SIG field of the 11be standard, and the like illustrated in FIG. 2. The frame generator 10003a-1 generates a first codeword block and a second codeword block corresponding to the first MPDU and the second MPDU based on the PHY header, and the transmitter 10003b-1 of the radio communication apparatus 1-1 transmits the PPDU including the first codeword block and the second codeword block allocated to the resource unit in the wireless channel.

In a case of retransmitting the first MPDU or the second MPDU under the same condition as that at the time of the initial transmission, the transmitter 10003b-1 according to the present embodiment may allow configuration of the HARQ in a field of the PHY header overlapping that used at the time of the initial transmission, and may perform packet combining on the first MPDU or the second MPDU retransmitted using the control information stored in the reception buffer.

For the AID, the higher layer unit 10001-1 of the radio communication apparatus 1-1 according to the present embodiment may configure the MPDU at the time of the initial transmission (hereinafter, also referred to as the initial transmission MPDU) as the AID 1 and the MPDU at the time of the retransmission (hereinafter, also referred to as the retransmission MPDU) as the AID 2, thus configuring the ARQ for the retransmission MPDU corresponding to the AID 2. In a case that ARQ is configured to the AID, the higher layer unit 10001-1 may generate control information related to a packet combining method of the PHY layer including a method of allocating the first MPDU and the second MPDU of the MAC layer to the resource unit, the AIDs assigned to the first MPDU and the second MPDU, and the configuration of ARQ. The frame generator 10003a-1 of the radio communication apparatus 1-1 according to the present embodiment generates a PPDU including the PHY header reflecting the control information, the first MPDU, and the second MPDU, and then configures, in the PHY header, a PLCP preamble for synchronization detection and a PLCP header for determining a Modulation and Coding Scheme (MCS) according to a received signal strength. However, in a case that the ARQ is added to the control information, the PLCP preamble or the PLCP header includes no information element related to the packet combining method of the PHY layer. The frame generator 10003a-1 generates a first codeword block and a second codeword block corresponding to the first MPDU and the second MPDU based on the PHY header, and the transmitter 10003b-1 of the radio communication apparatus 1-1 transmits a PPDU including the first codeword block and the second codeword block allocated to the resource unit in the wireless channel.

The radio communication apparatus 1-1 according to the present embodiment indicates, as ARQ/HARQ, the retransmission scheme included in the control information notified by the MAC layer of the higher layer unit 10001-1, thus allowing the control information to be configured to indicate whether to generate control information related to the packet combining method of the PHY layer.

In a case of reporting capability information (Capability, Capability element, Capabilityinformation) included in the radio communication apparatus 1-1 by using a beacon frame, a probe response frame, or the like, then the radio communication apparatus 1-1 according to the present embodiment can include, in the capability information, control information indicating whether to configure the ARQ/HARQ in the PHY header of a frame transmitted by the radio communication apparatus 1-1. The radio communication apparatus 1-1 can refuse the connection, to the radio communication apparatus 1-1, of a communication apparatus that cannot interpret a frame configured with the ARQ/HARQ.

The radio communication apparatus 1-1 can determine whether to configure the HARQ in a frame including the PSDU transmitted by the radio communication apparatus 1-1, depending on the length of the PSDU. For example, in a case that the length of the PSDU exceeds a prescribed length, the radio communication apparatus may avoid configuring the HARQ in the frame including the PSDU. Here, the length of the PSDU can be the number of information bits included in the PSDU, the number of bits included in a codeword block subjected to error correction coding, the time length of a frame included in the PSDU, or the like.

In a case that the HARQ is configured, the radio communication apparatus 1-1 can change the format of the control information between the initial transmission and the retransmission. The control information format of the initial transmission is also referred to as a first control information format, and the control information format of the retransmission is also referred to as a second control information format. The first control information format includes a part or all of the AID 1, the coding scheme, and the MCS (modulation mode). The second control information format includes a part or all of the AID 2, the modulation scheme, and the RV. Note that at least the coding rate and the coding scheme are common to the initial transmission and the retransmission and thus need not be included in the second control information. In a case that the initial transmission corresponds to RV0, the first control information format does not include the RV. Accordingly, the second control information format may be obtained by replacing the coding scheme and/or the coding rate with the RV in the first control information format.

The radio communication apparatus 1-1 can configure the ARQ/HARQ in the transmission frame only within the period of the TXOP acquired by using the control frame such as the RTS frame or the CTS frame. The radio communication apparatus can include, in the frame for acquiring the TXOP, information indicating that the ARQ/HARQ is configured or may be configured in a frame transmitted within the period of the TXOP. The radio communication apparatus can transmit, to multiple radio communication apparatuses, the frame for acquiring the TXOP. The radio communication apparatus can include, in the frame for acquiring the TXOP, information indicating multiple destination radio communication apparatuses (for example, information including multiple AIDs or information directly indicating multiple AIDs). The radio communication apparatus that receives the frame for acquiring the TXOP and that is one of the destinations can transmit a response frame in response to the frame for acquiring the TXOP. In this case, the response frame may include information indicating whether the radio communication apparatus can interpret a frame configured with the ARQ/HARQ. In response to the frame for acquiring the TXOP, the response frame can be transmitted only in a case that the radio communication apparatus can interpret the frame configured with the ARQ/HARQ.

The configuration of the ARQ/HARQ can be associated with the size of the resource unit (the number of subcarriers or tones constituting the resource unit). For example, the radio communication apparatus 1-1 can configure the HARQ in a resource unit having a size equal to or larger than a prescribed value. The radio communication apparatus 1-1 can configure the HARQ in a resource unit including OFDM signals the number of which is equal to or greater than a prescribed value.

The configuration of the ARQ/HARQ can be associated with the number of resource units included in a frame. For example, in a case that the number of resource units configured in a prescribed bandwidth is equal to or greater than a prescribed value, the radio communication apparatus 1-1 can configure the HARQ in each of the resource units.

The configuration of the ARQ/HARQ can be associated with the spatial multiplexing order of data or users configured in the resource unit. For example, the radio communication apparatus 1-1 can refrain from configuring the HARQ in the resource unit in which the spatial multiplexing is configured. The radio communication apparatus 1-1 can configure the HARQ in the resource unit in which a spatial multiplexing order equal to or less than a prescribed value is configured.

The configuration of the ARQ/HARQ may be associated with the length of the TXOP obtained before transmitting the frame. For example, the radio communication apparatus 1-1 can configure the HARQ for a frame transmitted within a TXOP longer than a prescribed value. The radio communication apparatus 1-1 can also configure the HARQ for a frame transmitted within a TXOP acquired by another apparatus instead of the TXOP acquired by the radio communication apparatus 1-1. In a case that the radio communication apparatus 1-1 configures the HARQ for the frame transmitted within the TXOP acquired by another apparatus, the configuration of the HARQ can be determined based on the information described in a trigger frame (the frame causing the radio communication apparatus 1-1 to transmit a frame) transmitted by the communication apparatus acquiring the TXOP.

For a retransmission frame for a frame in which the HARQ is configured, in a case that a prescribed period elapses from transmission of the initial transmission frame until transmission of the retransmission frame, the radio communication apparatus 1-1 can refrain from configuring the HARQ in the retransmission frame. In other words, in a case that an elapsed time equal to or longer than a prescribed value occurs between the transmission timing of the initial transmission frame and the transmission timing of the retransmission frame, the radio communication apparatus 1-1 does not expect that the frames are combined in the PHY layer. Similarly, a communication apparatus that has received a frame in which the HARQ is configured as the initial transmission frame can also be configured not to perform packet combining in the PHY layer in a case that the retransmission frame is received after a prescribed time has elapsed since the initial transmission frame is received. A condition for allowing the radio communication apparatus 1-1 to configure the HARQ in the retransmission frame may be that the retransmission frame can be transmitted before a prescribed time elapses after the initial transmission frame is transmitted.

The radio communication apparatus 1-1 can prohibit transmission of the frame in which the HARQ is configured in the TXOP acquired by the radio communication apparatus 1-1. The radio communication apparatus 1-1 can configure, in the TXOP acquired by the radio communication apparatus 1-1, the period during which transmission of the frame configured with the HARQ is prohibited. The interval during which the period for prohibiting the transmission of the frame configured with the HARQ is configured is not limited to the TXOP. For example, the radio communication apparatus 1-1 may configure, between periodically transmitted beacon frames, the period for prohibiting the transmission of the frame configured with the HARQ. Of course, the period for allowance can be configured instead of the period for prohibition.

The radio communication apparatus 2-1 according to the present embodiment receives the transmission frame from the radio communication apparatus 1-1. The signal demodulator 10004b-1 of the radio communication apparatus 2-1 according to the present embodiment decodes the codeword of the PSDU included in the received transmission frame. Then, the decoding result is transferred to the higher layer unit 10001-1. The higher layer unit 10001-1 performs error detection on the frame and determines whether the frame is correctly decoded. The error detection includes error detection using an error detection code (e.g., a cyclic redundancy check (CRC) code) assigned to the received transmission frame, and error detection using an error detection code (e.g., low-density parity-check code (LDPC)) having an error detection function from the first.

In a case that the configuration of the retransmission scheme indicates the ARQ, the signal demodulator 10004b-1 of the radio communication apparatus 2-1 according to the present embodiment reads, from the PHY header, the prescribed information bit length and coding rate specified by the MCSs, and calculates the prescribed information bit length (codeword block length) to be decoded. Then, the signal demodulator 10004b-1 performs, for each codeword block, decoding processing on the PSDU subjected to error correction coding. The MAC layer of the higher layer unit 10001-1 determines whether the MPDU or the A-MPDU has correctly been decoded from the decoded PSDU. For example, in the example of FIG. 16, the MAC layer of the higher layer unit 10001-1 detects an error in MPDU #2 and thus transmits, to the radio communication apparatus 1-1, the Block ACK indicating that MPDU #2 is a NACK. In order to transmit MPDU #2 and succeeding new MPDUs #4 and #5, the radio communication apparatus 1-1 generates blocks #9 to #16 with the coded block length and generates a retransmission frame. Note that the retransmission frame may exclusively include MPDU #2. In the blocking processing of FIG. 16, the prescribed bit length used by the MAC layer to separate the PSDU does not match an allocation of multiple prescribed bit lengths used by the PHY layer to separate the PSDU. Accordingly, MPDU #2 included in the retransmission frame and the initially transmitted MPDU #2 form different codewords, and thus the signal demodulator 10004b-1 of the radio communication apparatus 2-1 does not perform packet combining.

Description will be given of an example of a procedure in which the signal demodulator 10004b-1 of the radio communication apparatus 2-1 performs decoding in a case that the configuration of the retransmission scheme indicates the ARQ. First, a first coded bit length for the PSDU is obtained based on the number of OFDM symbols and the MCS in the received frame. Then, the LDPC codeword block length is obtained from the first coded bit length. For example, in the example of FIG. 9, in a case that the first coded bit length is 648 bits or less, the LDPC codeword block length is 648 bits. In a case that the first coded bit length is greater than 648 bits and 1296 bits or less, the LDPC codeword block length is 1296 bits. In a case that the first coded bit length is greater than 1296 bits and 1944 bits or less, the LDPC codeword block length is 1944 bits. In a case that the first coded bit length is 1944 bits or less, the number of LDPC codeword blocks is 1. In a case that the first coded bit length is greater than 1944 bits and 2592 bits or less, the LDPC codeword block length is 1296 bits and the number of LDPC codeword blocks is 2. In a case that the LDPC codeword block length is larger than 2592 bits, the LDPC codeword block length is 1944 bits, and the number of LDPC codeword blocks can be calculated as ceil (first coded bit length/1944) from the first coded bit length and 1944 bits corresponding to the LDPC codeword block length. Then, the shortening bit length and the puncturing bit length are calculated to obtain the codeword block length. Then, the first coded bits are divided into codeword blocks. Reverse processing of the shortening processing and puncturing processing performed on the transmission side is performed on the codeword block to generate an LDPC codeword block. In the reverse processing of the shortening processing, a Log Likelihood Ratio (LLR) having a large absolute value indicating bit 0 is inserted at the position of the shortening bit discarded on the transmission side. In the reverse processing of the puncturing processing, an LLR having a value of 0 is inserted at the position of the puncturing bit discarded on the transmission side. The LDPC codeword block is subjected to error correction decoding to obtain an LDPC information block.

In a case that the configuration of the retransmission scheme indicates the HARQ, the signal demodulator 10004b-1 of the radio communication apparatus 2-1 according to the present embodiment reads, from the PHY header, the information fields of the coding rate and coded block length specified by the MCS, and calculates the codeword block length. Then, the signal demodulator 10004b-1 performs the decoding processing on the PSDU for each codeword block, and transfers the decoding result to the higher layer unit 10001-1. The MAC layer of the higher layer unit 10001-1 performs error detection and determines whether the MPDU or the A-MPDU has correctly been decoded from the decoded PSDU. In the example of FIG. 17, the MAC layer of the higher layer unit 10001-1 detects an error with MPDU #2 and thus transmits, to the radio communication apparatus 1-1, the Block ACK indicating that MPDU #2 is a NACK. The Block ACK frame may include, in the information field, the sequence number in the information block corresponding to the sequence number of the MPDU in which an error has been detected. The radio communication apparatus 1-1 can transmit MPDU #2 and succeeding new MPDUs #4 and #5, and generates blocks #10 to #18 with the information block length and configures a retransmission frame. Note that the retransmission frame may exclusively include MPDU #2. In a case that the configuration of the retransmission scheme indicates the HARQ, the prescribed bit length used by the MAC layer to separate the PSDU matches an allocation of multiple prescribed bit lengths used by the PHY layer to separate the PSDU. Accordingly, the signal demodulator 10004b-1 of the radio communication apparatus 2-1 can perform packet combination on the retransmitted MPDU #2 and the initially transmitted MPDU #2 stored in a buffer, leading to increased received power, a produced time diversity effect, and the like.

Description will be given of an example of a procedure in which the signal demodulator 10004b-1 of the radio communication apparatus 2-1 performs decoding in a case that the configuration of the retransmission scheme indicates the HARQ. First, the second coded bit length for the MPDU is obtained based on the number of OFDM symbols and the MCS in the received frame. Then, the LDPC codeword block length is obtained from the second coded bit length. For example, in a case that the second coded bit length is 648 bits or less, the LDPC codeword block length is 648 bits. Next, in a case that the second coded bit length is greater than 648 bits and 1296 bits or less, the LDPC codeword block length is 1296 bits. In a case that the second coded bit length is greater than 1296 bits and 1944 bits or less, the LDPC codeword block length is 1944 bits. Note that in a case that the second coded bit length is 1944 bits or less, the number of LDPC codeword blocks is 1. In a case that the second coded bit length is greater than 1944 bits and 2592 bits or less, the LDPC codeword block length is 1296 bits and the number of LDPC codeword blocks is 2. In a case that the LDPC codeword block length is larger than 2592 bits, the LDPC codeword block length is 1944 bits, and the number of LDPC codeword blocks can be calculated as ceil (second coded bit length/1944) from the second coded bit length and 1944 bits corresponding to the LDPC codeword block length. Then, the shortening bit length and the puncturing bit length are calculated to obtain the codeword block length. Then, the second coded bits are divided into codeword blocks. Reverse processing of the shortening processing and puncturing processing performed on the transmission side is performed on the codeword block to generate an LDPC codeword block. In the reverse processing of the shortening processing, a Log Likelihood Ratio (LLR) having a large absolute value indicating bit 0 is inserted at the position of the shortening bit discarded on the transmission side. In the reverse processing of the puncturing processing, an LLR having a value of 0 is inserted at the position of the puncturing bit discarded on the transmission side. The LDPC codeword block is subjected to error correction decoding to obtain an LDPC information block. In the case of retransmission, error correction decoding is performed after LLR combining of the initially transmitted LDPC codeword block and the retransmitted LDPC codeword block. In the case of IR, decoding is performed at the mother coding rate.

An example of a decoding procedure will be described that is used in a case that the configuration of the retransmission scheme indicates the HARQ and each coding rate of the MCS has the first LDPC codeword block length, the second LDPC codeword block length, and the third LDPC codeword block length. In a case that the second coded bit length is equal to or less than the first LDPC codeword block length, the LDPC codeword block length corresponds to the first LDPC codeword block length. In a case that the second coded bit length is greater than the first LDPC codeword block length and is equal to or less than the second LDPC codeword block length, the LDPC codeword block length corresponds to the second LDPC codeword block length. In a case that the second coded bit length is greater than the second LDPC codeword block length and is equal to or less than the third LDPC codeword block, the LDPC codeword block length corresponds to the third LDPC codeword block length. Note that in a case that the LDPC codeword block length is equal to or less than the third LDPC codeword block length, the number of LDPC codeword blocks is 1. In a case that the second LDPC coded bit length is greater than the third LDPC codeword block length and is equal to or less than twice the second LDPC codeword block length, the LDPC codeword block length corresponds to the second LDPC codeword block length and the number of LDPC codeword blocks is 2. In a case that the LDPC codeword block length is greater than twice the second LDPC codeword block length, the LDPC codeword block length corresponds to the third LDPC codeword block length, and the number of LDPC codeword blocks is calculated from the second coded bit length and the third LDPC codeword block length as ceil (second coded bit length/third LDPC codeword block length). Then, the shortening bit length and the puncturing bit length are calculated to obtain the codeword block length. Then, the second coded bits are divided into codeword blocks. Reverse processing of the shortening processing and puncturing processing performed on the transmission side is performed on the codeword block to generate an LDPC codeword block. In the reverse processing of the shortening processing, a Log Likelihood Ratio (LLR) having a large absolute value indicating bit 0 is inserted at the position of the shortening bit discarded on the transmission side. In the reverse processing of the puncturing processing, an LLR having a value of 0 is inserted at the position of the puncturing bit discarded on the transmission side. The LDPC codeword block is subjected to error correction decoding to obtain an LDPC information block. In the case of the retransmission, error correction decoding is performed after LLR combining of the first codeword block and one or multiple second LDPC codeword blocks.

On the other hand, in a case that the information field of the PHY header of the received transmission frame stores the index of the coded block length, then in the decoding processing performed by the signal demodulator 10004b-1 according to the present embodiment, the codeword block length can be calculated by referencing the index in the table or the calculation formula. Then, the signal demodulator 10004b-1 decodes each MPDU for each codeword block length, and transfers the decoding result to the higher layer unit 10001-1. In a case that multiple block lengths corresponding to the lengths of the respective MPDUs constituting the A-MPDU are stored in the PHY header, reduced transmission efficiency is indicated by an increased ratio of overheads occupying the PHY layer caused by an increased number of MPDUs aggregated in the MAC layer. In the decoding processing using the table or the calculation formula, each MPDU length can be referenced by using the index, and packet combination with high transmission efficiency can be achieved due to reduction in overheads.

Note that in a case that the configuration of the retransmission scheme indicates the HARQ, the radio communication apparatus 2-1 may obtain a codeword block for decoding from the first coded bit length for the PSDU in a case that a prescribed MCS is applied with a prescribed MPDU length.

On the other hand, the radio communication apparatus 2-1 according to the present embodiment receives the transmission frame from the radio communication apparatus 1-1. The signal demodulator 10004b-1 of the radio communication apparatus 2-1 according to the present embodiment first decodes the PHY header of the PPDU that is a received transmission frame, and in a case that the HARQ is configured in the PHY header, performs packet combining of the frame based on information elements related to the packet combining method such as the modulation and coding scheme (MCS), the coding scheme, RU-related information, and the RV for the first MPDU and the second MPDU in the PHY header, and decodes the codewords of the PPDU including the first codeword block and the second codeword block. Then, the decoding result is transferred to the higher layer unit 10001-1. The higher layer unit 10001-1 performs error detection on the PPDU and determines whether the PPDU is correctly decoded. The error detection includes error detection using an error detection code (e.g., a cyclic redundancy check (CRC) code) assigned to the received transmission frame, and error detection using an error detection code (e.g., low-density parity-check code (LDPC)) having an error detection function from the first. First, the result of decoding of the PPDU of the PHY layer in the signal demodulator 10004b-1 is transferred to the MAC layer. In the MAC layer, the frame of the MAC layer is restored from the transferred result of decoding. Then, error detection is performed in the MAC layer, and whether the frame of the MAC layer has been properly restored is determined, the frame of the MAC layer being transmitted by the station apparatus as a transmission source of the reception frame. The signal demodulator 10004b-1 can perform error detection on the received signal by performing decoding processing in the PHY layer. Here, the decoding processing includes decoding of error correction codes applied to the received signal. Here, the error detection includes error detection using an error detection code (e.g., a cyclic redundancy check (CRC) code) that has been given to the received signal in advance, and error detection using an error correction code (e.g., low-density parity-check code (LDPC)) having an error detection function from the first. The decoding processing in the PHY layer can be applied for each coding block.

On the other hand, in a case that the ARQ is configured in the PHY header of the received transmission frame, the decoding processing of the signal demodulator 10004b-1 according to the present embodiment does not include packet combining of the frame, but includes decoding the codewords of the PPDU including the first codeword block and the second codeword block, and transferring the decoding result to the higher layer unit 10001-1.

With the ARQ configured, the radio communication apparatus 2-1 according to the present embodiment receives the AID 1 from the radio communication apparatus 1-1. With the HARQ configured, the radio communication apparatus 2-1 receives the AID 1 or the AID 2 from the radio communication apparatus 1-1. With the HARQ configured, the radio communication apparatus 2-1 can determine that the transmission is the initial transmission in a case that the AID 1 is received, and can determine that the transmission is the retransmission in a case that the AID 2 is received. With the HARQ configured, the radio communication apparatus 2-1 receives the AID 1 or the AID 2 in each MPDU or each resource unit.

With the HARQ configured, the radio communication apparatus 2-1 according to the present embodiment can receive different formats of control information between the initial transmission and the retransmission. In a case of receiving the first control information format, the radio communication apparatus 2-1 can determine that the transmission is the initial transmission, and in a case of receiving the second control information format, the radio communication apparatus 2-1 can determine that the transmission is the retransmission. The first control information format includes part or all of the AID 1, the coding scheme, and the modulation mode (MCS). The second control information format includes a part or all of the AID 2, the modulation scheme, and the RV. With the HARQ configured, the radio communication apparatus 2-1 can determine that the initial transmission corresponds to RV0. In a case of receiving the second control information format, the radio communication apparatus 2-1 can replace the coding scheme and/or the coding rate with the RV in the first control information format.

Although the communication apparatuses according to an aspect of the present invention can perform communication in a frequency band (frequency spectrum) that is a so-called unlicensed band that does not require permission to use from a country or a region, available frequency bands are not limited thereto. Although permission to use a specific service is given from a country or a region, the communication apparatuses according to an aspect of the present invention can exhibit the effect that can be brought by the purpose of preventing interference between frequencies, and the like, in a frequency band called a white band that is not actually used (e.g., a frequency band that is allocated for television broadcasting but is not used depending on regions), or a shared spectrum (shared frequency band) that is expected to be shared by multiple service providers, for example.

A program operated in the radio communication apparatuses according to an aspect of the present invention is a program (a program for causing a computer to function) for controlling a CPU or the like to implement the functions of the aforementioned embodiments according to an aspect of the present invention. In addition, information handled by these apparatuses is temporarily accumulated in a RAM at the time of processing, is then stored in various types of ROMs and HDDs, and is read by the CPU as necessary to be corrected and written. A semiconductor medium (e.g., a ROM, a non-volatile memory card, etc.), an optical recording medium (e.g., a DVD, an MO, an MD, a CD, a BD, etc.), a magnetic recording medium (e.g., a magnetic tape, a flexible disk, etc.), and the like can be examples of recording media for storing programs. In addition to implementing the functions of the aforementioned embodiments by performing loaded programs, the functions of the present invention may be implemented in processing performed in cooperation of an operating system, other application programs, and the like based on instructions of those programs.

In a case of delivering these programs to market, the programs can be stored and distributed in a portable recording medium, or transferred to a server computer connected via a network such as the Internet. In this case, storage apparatuses of the server computer are also included in an aspect of the present invention. A part or an entirety of the communication apparatuses in the aforementioned embodiments may be implemented as an LSI that is typically an integrated circuit. The functional blocks of the communication apparatuses may be individually implemented as chips or may be partially or completely integrated into a chip. In a case that the functional blocks are made as integrated circuits, an integrated circuit controller for controlling them is added.

The circuit integration technique is not limited to LSI, and may be realized as dedicated circuits or a multi-purpose processor. Moreover, in a case that a circuit integration technology that substitutes an LSI appears with the advance of the semiconductor technology, it is also possible to use an integrated circuit based on the technology.

Note that, the invention of the present application is not limited to the above-described embodiments. The radio communication apparatus according to the invention of the present application is not limited to the application in the mobile station apparatus, and, needless to say, can be applied to a fixed-type electronic apparatus installed indoors or outdoors, or a stationary-type electronic apparatus, for example, an AV apparatus, a kitchen apparatus, a cleaning or washing machine, an air-conditioning apparatus, office equipment, a vending machine, and other household apparatuses.

Although the embodiments of the invention have been described in detail above with reference to the drawings, a specific configuration is not limited to the embodiments, and designs and the like that do not depart from the essential spirit of the invention also fall within the claims.

### INDUSTRIAL APPLICABILITY

An aspect of the present invention can be preferably used in a communication apparatus and a communication method.

### REFERENCE SIGNS LIST

1-1, 1-2, 2-1 to 2-6, 2A, 2B Radio communication apparatus
3-1, 3-2 Control range
10-1 Radio communication apparatus
10001-1 Higher layer unit
10002-1 Controller
10002a-1 CCA unit
10002b-1 Backoff unit
10002c-1 Transmission determination unit
10003-1 Transmitter
10003a-1 Physical layer frame generator
10003b-1 Radio transmitter
10004-1 Receiver
10004a-1 Wireless receiver
10004b-1 Signal demodulator
10005-1 Antenna unit
2000, 2004, 2100 Information bit
2001, 2005, 2101 Shortening bit
2002-1 to 2002-5, 2006-1 to 2006-5 Parity block
2003, 2007-1 to 2007-5 Puncturing bit
2102 Initial-transmission parity bit
2103 Initial-transmission puncturing bit
2104-1 to 2104-4 Retransmission parity block

1. A communication apparatus comprising:
a higher layer unit configured to configure a retransmission scheme;
a physical layer frame generator configured to generate a frame using a codeword; and
a radio transmitter configured to transmit the frame, wherein
in a case that a configuration of the retransmission scheme indicates a Hybrid Auto Repeat reQuest (HARQ), the physical layer frame generator:
encodes, at a prescribed coding rate, a Low Density Parity Check (LDPC) information block including information bits, to generate a parity bit sequence; and
divides the parity bit sequence into blocks the number of which is given by a coding rate indicated by a Modulation and Coding Scheme (MCS), to generate multiple parity blocks,
each of the multiple parity blocks is associated with the number of retransmissions,
the codeword is generated based on the information bits and one of the multiple parity blocks, and
in a case that the LDPC information block includes the information bits and shortening bits, the number of bits of at least one parity block of the multiple parity blocks is reduced based on the number of shortening bits.

2. The communication device according to claim 1, wherein
the number of blocks given by the coding rate indicated by the MCS increases as the coding rate increases.

3. The communication device according to claim 1, wherein
in the case that the LDPC information block includes the information bits and the shortening bits, the physical layer frame generator punctures a prescribed number of bits from the parity bit sequence and then divides the parity bit sequence into blocks the number of which is given by the coding rate indicated by the MCS, to generate the multiple parity blocks.

4. The communication device according to claim 1, wherein
in the case that the LDPC information block includes the information bits and the shortening bits, the physical layer frame generator punctures a prescribed number of bits from one parity block of the multiple parity blocks, and generates the codeword based on the punctured parity block and the information bits.

5. The communication device according to claim 1, wherein
in the case that the LDPC information block includes the information bits and the shortening bits,
the physical layer frame generator:
decreases, at a time of initial transmission, the number of bits of the parity block included in the codeword, based on the number of the shortening bits; and
decreases, at a time of retransmission, the number of bits of the information bits included in the codeword, based on the number of the shortening bits.

6. A communication method comprising the steps of:
configuring a retransmission scheme;
generating a frame using a codeword; and
transmitting the frame, wherein
in a case that a configuration of the retransmission scheme indicates a Hybrid Auto Repeat reQuest (HARQ), the method includes:
encoding, at a prescribed coding rate, a Low Density Parity Check (LDPC) information block including information bits, to generate a parity bit sequence; and
dividing the parity bit sequence into blocks the number of which is given by a coding rate indicated by a Modulation and Coding Scheme (MCS), to generate multiple parity blocks,
each of the multiple parity blocks is associated with the number of retransmissions,
the codeword is generated based on the information bits and one of the multiple parity blocks, and
in a case that the LDPC information block includes the information bits and shortening bits, the number of bits of at least one parity block of the multiple parity blocks decreases based on the number of shortening bits.
